(19) United States
(12) Patent Application Publication
(10) Pub. No.: US 2026/0020448 A1
(43) Pub. Date: Jan. 15, 2026

(54) PIXEL, DISPLAY DEVICE INCLUDING THE SAME AND ELECTRONIC DEVICE INCLUDING DISPLAY DEVICE

(71) Applicant: SAMSUNG DISPLAY CO., LTD., YONGIN-SI (KR)

(72) Inventors: TAEGYUN KIM, Yongin-si (KR); JAEYONG JANG, Yongin-si (KR); MINJAE JEONG, Yongin-si (KR)

(21) Appl. No.: 19/266,603

(22) Filed: Jul. 11, 2025

(30) Foreign Application Priority Data
Jul. 15, 2024 (KR) 10-2024-0093085

(51) Int. Cl. H10K 59/123; G09G 3/3225; H10K 59/122; H10K 59/131; H10K 59/35

(52) U.S. Cl. CPC H10K 59/123; G09G 3/3225; H10K 59/122; H10K 59/131; H10K 59/352; H10K 59/353; G09G 2320/0257; G09G 2320/0673; G09G 2330/023

(57) ABSTRACT

A display device is provided that includes a light emitting element and a pixel drive circuit connected to the light emitting element. The light emitting element is connected between a first power line configured to receive a first power voltage and a first node. The pixel drive circuit includes a drive transistor and a plurality of switching transistors. The drive transistor is an N-type transistor, and at least one of the plurality of switching transistors is a P-type transistor.

### CROSS-REFERENCE TO RELATED APPLICATIONS

This U.S. patent application claims priority under 35 U.S.C. § 119 to Korean Patent Application No. 10-2024-0093085 filed on Jul. 15, 2024, in the Korean Intellectual Property Office, the disclosure of which is incorporated by reference in its entirety herein.

### 1. TECHNICAL FIELD

Embodiments of the present disclosure are directed to a pixel for reducing power consumption, a display device including the same and an electronic device including the display device.

### 2. DISCUSSION OF RELATED ART

An emissive display device is a type of display that generates light from each pixel, without requiring a backlight. The emissive display device has high contrast ratios, fast response times, wide viewing angles and lower power consumption.

The emissive display device includes pixels connected to data lines and scan lines. In general, each of the pixels includes a light emitting element and a pixel circuit for controlling the amount of current flowing to the light emitting element. The pixel circuit controls the amount of current flowing to the light emitting element based on a data signal. The light emitting element then produces light with a luminance depending on the amount of current it receives.

However, the pixel circuit may require large voltage swings to properly turn off its transistors. Such large voltage swings increase power consumption, as power usage scales with the square of the voltage difference. Moreover, they place greater demands on the peripheral circuitry, such as gate drivers and voltage generators, which need to support high-voltage operation. This can lead to increased circuit complexity, larger non-display areas, reduced power efficiency, and potential long-term reliability issues. Additionally, as the light emitting elements degrade over time, variations in pixel current can occur, resulting in luminance drift or image retention.

### SUMMARY

Embodiments of the present disclosure may provide a pixel for reducing power consumption and enhancing display reliability, a display device including the pixel and an electronic device including the display device.

According to an embodiment, a display device includes a pixel including a light emitting element and a pixel drive circuit connected to the light emitting element, the light emitting element being connected between a first power line configured to receive a first power voltage and a first node. The pixel drive circuit includes a first transistor including a first electrode electrically connected to the first node, a second electrode electrically connected to a second node, and a gate electrode electrically connected to a third node, a second transistor including a first electrode electrically connected to a data line configured to receive a data signal, a second electrode electrically connected to the third node, and a gate electrode configured to receive a scan signal, and a third transistor including a first electrode electrically connected to a first initialization voltage line configured to receive a first initialization voltage, a second electrode electrically connected to the first node, and a gate electrode configured to receive a compensation scan signal. The first transistor is an N-type transistor, the second transistor is an N-type transistor or a P-type transistor, and the third transistor is a P-type transistor. In an embodiment, a high level of the compensation scan signal is less than or equal to 10V.

The pixel drive circuit may further include a fourth transistor including a first electrode electrically connected to a reference voltage line configured to receive a reference voltage, a second electrode electrically connected to the third node, and a gate electrode configured to receive an initialization scan signal, wherein the fourth transistor is an N-type transistor or a P-type transistor.

During an initialization period, the initialization scan signal may have an active level, and the compensation scan signal and the scan signal may have an inactive level. During a compensation period, the compensation scan signal and the initialization scan signal may have an active level, and the scan signal may have an inactive level.

The pixel drive circuit may further include a first capacitor connected between the second node and the third node and a second capacitor connected between the second node and a second power line configured to receive a second power voltage having a lower voltage level than the first power voltage.

The pixel drive circuit may further include a fifth transistor including a first electrode electrically connected to the first node, a second electrode electrically connected to the first electrode of the first transistor, and a gate electrode that receives a first light emission signal, wherein the fifth transistor is a P-type transistor.

The pixel drive circuit may further include a sixth transistor including a first electrode electrically connected to the second node, a second electrode electrically connected to a second power line configured to receive a second power voltage having a lower voltage level than the first power voltage, and a gate electrode that receives a second light emission signal, wherein the sixth transistor is an N-type transistor or a P-type transistor.

A high level of the first light emission signal may be less than or equal to 10V.

During an initialization period, the second light emission signal may have an active level, and the first light emission signal may have an inactive level. During a compensation period, the first light emission signal may have an active level, and the second light emission signal may have an inactive level.

A voltage value of the first power may be less than or equal to 8.4V.

A voltage value of each of the first power voltage and the first initialization voltage may be about 8.4V, a voltage value of the second power voltage may be about 0V, and a high level of each of the compensation scan signal and the first light emission signal may be about 8.4V.

A voltage value of each of the first power voltage and the first initialization voltage may be about 7V, and a voltage value of the second power voltage may be about 0V, and wherein a high level of each of the compensation scan signal and the first light emission signal may be about 7V.

The pixel drive circuit may further include a fifth transistor including a first electrode electrically connected to the first node, a second electrode electrically connected to the first electrode of the first transistor, and a gate electrode that receives a light emission signal and a sixth transistor including a first electrode electrically connected to the second node, a second electrode electrically connected to a second power line configured to receive a second power voltage having a lower voltage level than the first power, and a gate electrode configured to receive the light emission signal, and each of the fifth transistor and the sixth transistor may be a P-type transistor.

The pixel drive circuit may further include a seventh transistor including a first electrode electrically connected to the second node, a second electrode electrically connected to a second initialization voltage line configured to receive a second initialization voltage having a lower voltage level than the first initialization voltage, and a gate electrode configured to receive an input scan signal, and the seventh transistor may be an N-type transistor.

During an initialization period, the input scan signal may have an active level, and during a compensation period, the input scan signal may have an inactive level.

The pixel drive circuit may further include an eighth transistor including a first electrode electrically connected to the first initialization voltage line, a second electrode electrically connected to the first electrode of the first transistor, and a gate electrode that is configured to receive the compensation scan signal, and the eighth transistor may be a P-type transistor.

A voltage value of the first power may be about 8.4V, a voltage value of the second power may be about 0V, and a high level of the light emission signal may be less than or equal to 10V, and wherein a voltage value of the first initialization voltage may be about 8.4V, and a high level of the compensation scan signal may be less than or equal to 10V.

The light emitting element may include an anode, a cathode disposed over the anode, and an emissive layer and may include an intermediate layer disposed between the anode and the cathode. The anode may be electrically connected to the first power line, and the cathode may be electrically connected to the first node.

The display device may further include a pixel defining layer including an opening configured to expose at least a portion of the anode, a connecting electrode disposed on the pixel defining layer and electrically connected to the first node and the cathode, and a separator disposed on the pixel defining layer. In a contact area adjacent to the separator, a lower surface of the cathode may be in contact with an upper surface of the connecting electrode.

According to an embodiment, a display device includes a light emitting element that is connected between a first power line configured to receive a first power voltage and a first node and that includes a first electrode, an intermediate layer that is disposed on the first electrode and that includes an emissive layer, and a second electrode disposed on the intermediate layer, a pixel drive circuit that is connected to the light emitting element and that includes a drive transistor and a plurality of switching transistors, a pixel defining layer including an opening configured to expose at least a portion of the first electrode, a connecting electrode disposed on the pixel defining layer and electrically connected to the pixel drive circuit and the second electrode, and a separator disposed on the pixel defining layer. In a contact area adjacent to the separator, a lower surface of the second electrode is in contact with an upper surface of the connecting electrode. The drive transistor is an N-type transistor, and at least one of the plurality of switching transistors is a P-type transistor.

According to an embodiment, an electronic device includes a display device to provide an image and a processor to control an operation of the display device. The display device includes a pixel including a light emitting element and a pixel drive circuit connected to the light emitting element, the light emitting element being connected between a first power line configured to receive a first power voltage and a first node. The pixel drive circuit includes a first transistor including a first electrode electrically connected to the first node, a second electrode electrically connected to a second node, and a gate electrode electrically connected to a third node, a second transistor including a first electrode electrically connected to a data line configured to receive a data signal, a second electrode electrically connected to the third node, and a gate electrode configured to receive a scan signal, and a third transistor including a first electrode electrically connected to a first initialization voltage line configured to receive a first initialization voltage, a second electrode electrically connected to the first node, and a gate electrode configured to receive a compensation scan signal. The first transistor is an N-type transistor, the second transistor is an N-type transistor or a P-type transistor, and the third transistor is a P-type transistor. In an embodiment, a high level of the compensation scan signal is less than or equal to 10V.

### BRIEF DESCRIPTION OF THE FIGURES

The above and other objects and features of the present disclosure will become apparent by describing in detail embodiments thereof with reference to the accompanying drawings.

FIG. 1 is a block diagram of a display device according to an embodiment of the present disclosure.

FIG. 2 is a circuit diagram of a pixel of the display device according to an embodiment of the present disclosure.

FIG. 3 is a timing chart for explaining an operation of the pixel of FIG. 2 according to an embodiment of the present disclosure.

FIG. 4 is a circuit diagram of the pixel of the display device according to an embodiment of the present disclosure.

FIG. 5 is a timing chart for explaining an operation of the pixel of FIG. 4 according to an embodiment of the present disclosure.

FIG. 6 is a circuit diagram of a pixel of the display device according to an embodiment of the present disclosure.

FIG. 7 is a timing chart for explaining an operation of the pixel of FIG. 6 according to an embodiment of the present disclosure.

FIG. 8 is a circuit diagram of a pixel of the display device according to an embodiment of the present disclosure.

FIG. 9 is a timing chart for explaining an operation of the pixel of FIG. 8 according to an embodiment of the present disclosure.

FIG. 10 is a circuit diagram of a pixel of the display device according to an embodiment of the present disclosure.

FIG. 11 is a timing chart for explaining an operation of the pixel of FIG. 10 according to an embodiment of the present disclosure.

FIG. 12A is a schematic plan view illustrating a display panel of the display device according to an embodiment of the present disclosure.

FIG. 12B is a schematic plan view illustrating the display panel according to an embodiment of the present disclosure.

FIG. 13A is an enlarged plan view of a partial area of the display panel according to an embodiment of the present disclosure.

FIG. 13B is an enlarged plan view of a partial area of the display panel according to an embodiment of the present disclosure.

FIG. 13C is an enlarged plan view of a partial area of the display panel according to an embodiment of the present disclosure.

FIG. 13D is an enlarged plan view of a partial area of the display panel according to an embodiment of the present disclosure.

FIG. 14 is a sectional view of the display panel according to an embodiment of the present disclosure.

FIG. 15 is an enlarged sectional view of a partial area of the display panel according to an embodiment of the present disclosure.

FIG. 16 is a sectional view of a display panel of the display device according to an embodiment of the present disclosure.

FIG. 17 is a block diagram of an electronic device, according to an embodiment of the present disclosure.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Herein, identical reference numerals refer to identical components. As used herein, the term “and/or” includes all of one or more combinations defined by related components.

Terms such as first, second, and the like may be used to describe various components, but the components are not limited by these terms. The terms may be used for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the present disclosure will be described with reference to the accompanying drawings.

At least one embodiment of the present disclosure is directed to a pixel drive circuit for display devices that is specifically designed to reduce power consumption. The circuit employs a hybrid configuration of transistors, in which its drive transistor is an NMOS transistor and at least some of its switching transistors such as compensation and light emission control transistors are PMOS transistors. This mixed NMOS/PMOS combination enables pixels to operate with lower gate high voltages, significantly reducing the voltage swing between high and low logic levels needed for pixel operation. Since power consumption scales with the square of this voltage swing, this configuration results in a measurable reduction in power consumption. Additionally, by configuring the drive transistor as an NMOS and connecting a cathode of a light emitting element to a drain of the drive transistor, a stable source voltage may be maintained regardless of degradation in the light emitting element. This ensures the gate-source voltage of the drive transistor remains consistent, allowing the pixel to deliver a stable current output over time. As a result, the display is less susceptible to luminance drift, image retention, and non-uniform aging, thereby extending its useful lifespan and enhancing long-term image quality. In some embodiments, the design further simplifies pixel wiring by reusing an existing power line for source initialization, which can reduce the need for separate initialization voltages, shrink the non-display area, and enhance circuit reliability.

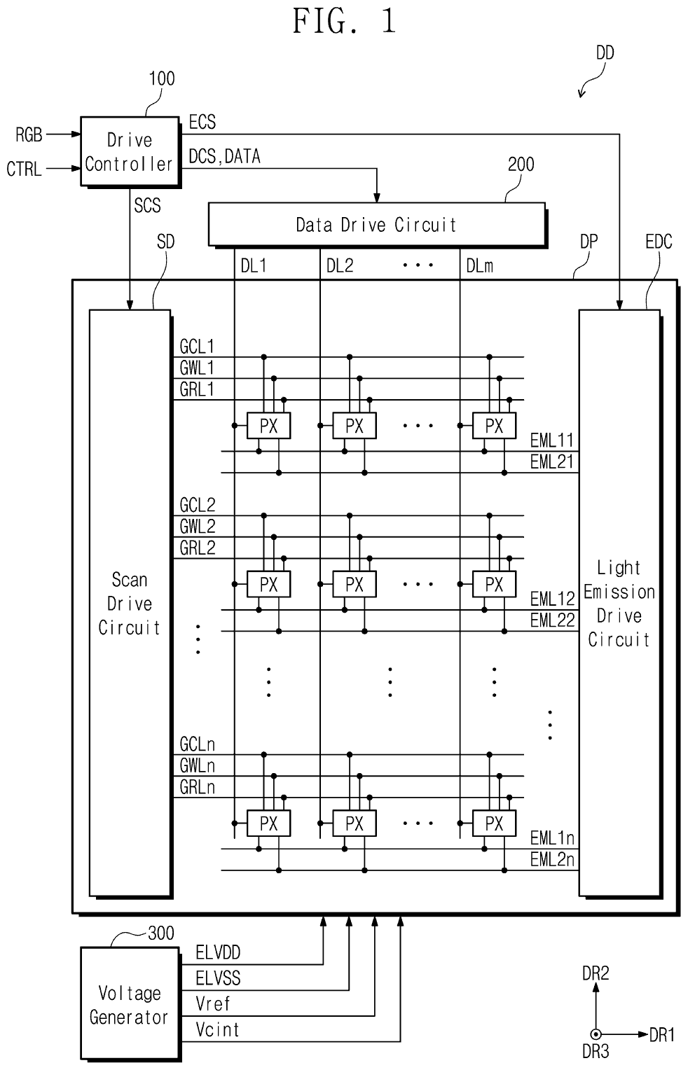

FIG. 1 is a block diagram of a display device DD according to an embodiment of the present disclosure.

Referring to FIG. 1, the display device DD may include a display panel DP, a drive controller 100 (e.g., a controller circuit), a data drive circuit 200, and a voltage generator 300.

The display panel DP according to an embodiment of the present disclosure may be an emissive display panel, but is not limited thereto. For example, the display panel DP may be an organic light emitting display panel, a quantum-dot light emitting display panel, a micro-LED display panel, or a nano-LED display panel. An emissive layer of the organic light emitting display panel may include an organic luminescent material. An emissive layer of the quantum-dot light emitting display panel may include quantum dots, quantum rods, and the like. An emissive layer of the micro-LED display panel may include micro LEDs. An emissive layer of the nano-LED display panel may include nano LEDs.

The drive controller 100 may receive an image signal RGB and a control signal CTRL. The drive controller 100 may generate an image data signal DATA by converting the data format of the image signal RGB according to the specification of an interface with the data drive circuit 200. The drive controller 100 may output a scan control signal SCS, a data control signal DCS, and a light emission drive control signal ECS.

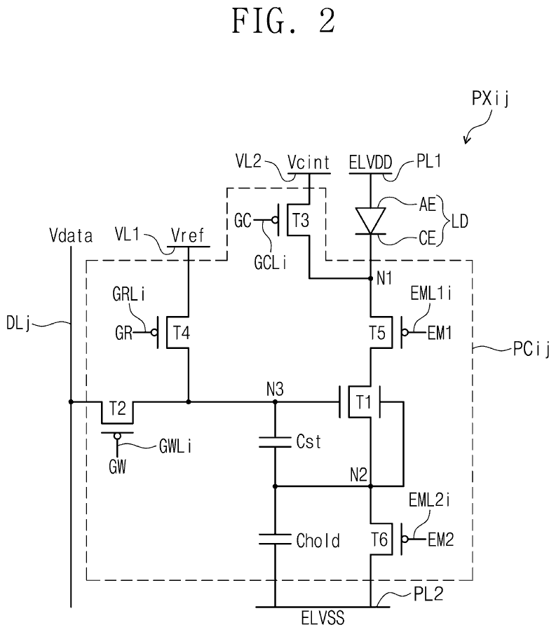

The data drive circuit 200 may receive the data control signal DCS and the image data signal DATA from the drive controller 100. The data drive circuit 200 may convert the image data signal DATA into data signals Vdata (refer to FIG. 2) and may output the data signals Vdata (refer to FIG. 2) to a plurality of data lines DL1 to DLm. The data signals Vdata (refer to FIG. 2) may be analog voltages corresponding to the gray level value of the image data signal DATA.

In an embodiment of the present disclosure, the data drive circuit 200 may output the data signals Vdata (refer to FIG. 2) corresponding to the image data signal DATA to the data lines DL1 to DLm during a frame period (e.g., a drive period), which corresponds to one frame of image data, to update pixels values for that frame.

The voltage generator 300 may generate voltages used for an operation of the display panel DP. In an embodiment of the present disclosure, the voltage generator 300 may generate first power ELVDD, second power ELVSS, a reference voltage Vref, and an initialization voltage Vcint.

The display panel DP may include scan lines GCL1 to GCLn, GWL1 to GWLn, and GRL1 to GRLn, light emission control lines EML11 to EML1n and EML21 to EML2n, the data lines DL1 to DLm, and pixels PX. The display panel DP may further include a scan drive circuit SD and a light emission drive circuit EDC.

The scan drive circuit SD may be disposed on a first side of the display panel DP. The scan lines GCL1 to GCLn, GWL1 to GWLn, and GRL1 to GRLn may extend from the scan drive circuit SD in a first direction DR1.

The light emission drive circuit EDC may be disposed on a second side of the display panel DP. The light emission control lines EML11 to EML1n and EML21 to EML2n may extend from the light emission drive circuit EDC in the direction opposite to the first direction DR1.

The scan lines GCL1 to GCLn, GWL1 to GWLn, and GRL1 to GRLn and the light emission control lines EML11 to EML1n and EML21 to EML2n may be spaced apart from one another in a second direction DR2.

The scan lines GCL1 to GCLn, GWL1 to GWLn, and GRL1 to GRLn may include the compensation scan lines GCL1 to GCLn, the write scan lines GWL1 to GWLn, and the initialization scan lines GRL1 to GRLn.

The light emission control lines EML11 to EML1n and EML21 to EML2n may include the first light emission control lines EML11 to EML1n and the second light emission control lines EML21 to EML2n.

The data lines DL1 to DLm may extend from the data drive circuit 200 in a direction opposite to the second direction DR2. The data lines DL1 to DLm may be spaced apart from one another in the first direction DR1.

In the embodiment illustrated in FIG. 1, the scan drive circuit SD and the light emission drive circuit EDC are disposed to face each other with the pixels PX therebetween. However, the present disclosure is not limited thereto. For example, the scan drive circuit SD and the light emission drive circuit EDC may be disposed adjacent to each other on the first side or the second side of the display panel DP. In an embodiment, the scan drive circuit SD and the light emission drive circuit EDC may be implemented with one circuit.

The plurality of pixels PX may be electrically connected to the scan lines GCL1 to GCLn, GWL1 to GWLn, and GRL1 to GRLn, the light emission control lines EML11 to EML1n and EML21 to EML2n, and the data lines DL1 to DLm. Each of the plurality of pixels PX may be electrically connected to four scan lines and two light emission control lines.

Each of the plurality of pixels PX may include a light emitting element LD (refer to FIG. 2) and a pixel circuit that controls light emission of the light emitting element LD (refer to FIG. 2).

The light emitting elements LD (refer to FIG. 2) of the plurality of pixels PX may generate light of different colors. For example, the plurality of pixels PX may include red pixels that generate red light, green pixels that generate green light, and blue pixels that generate blue light. Light emitting elements of the red pixels, light emitting elements of the green pixels, and light emitting elements of the blue pixels may include emissive layers formed of different materials.

The pixel circuit may include at least one transistor and at least one capacitor. The scan drive circuit SD and the light emission drive circuit EDC may include transistors formed through the same process as the transistors of the pixel circuit.

Each of the plurality of pixels PX may receive the first power ELVDD, the second power ELVSS, the reference voltage Vref, and the initialization voltage Vcint from the voltage generator 300.

The scan drive circuit SD may receive the scan control signal SCS from the drive controller 100. The scan drive circuit SD may output scan signals to the scan lines GCL1 to GCLn, GWL1 to GWLn, and GRL1 to GRLn in response to the scan control signal SCS.

The light emission drive circuit EDC may output light emission signals to the light emission control lines EML11 to EML1n and EML21 to EML2n in response to the light emission drive control signal ECS from the drive controller 100.

The drive controller 100 according to an embodiment of the present disclosure may determine a drive frequency and may control the data drive circuit 200, the scan drive circuit SD, and the light emission drive circuit EDC depending on the determined drive frequency.

FIG. 2 is a circuit diagram of a pixel PXij according to an embodiment of the present disclosure. Each of the plurality of pixels PX illustrated in FIG. 1 may have the same circuit configuration as the equivalent circuit diagram of the pixel PXij illustrated in FIG. 2.

Referring to FIG. 2, the pixel PXij may be connected to the j-th data line DLj among the data lines DL1 to DLm, the i-th compensation scan line GCLi among the compensation scan lines GCL1 to GCLn, the i-th write scan line GWLi among the write scan lines GWL1 to GWLn, the i-th initialization scan line GRLi among the initialization scan lines GRL1 to GRLn, the i-th first light emission control line EML1i among the first light emission control lines EML11 to EML1n, and the i-th second light emission control line EML2i among the second light emission control lines EML21 to EML2n. Here, “i” and “j” are natural numbers.

The pixel PXij may include the light emitting element LD and a pixel drive circuit PCij. The light emitting element LD may be a light emitting diode. For example, the light emitting element LD may be an organic light emitting diode including an organic emissive layer. The pixel drive circuit PCij may be connected to the light emitting element LD and may control the amount of current flowing through it, with the light emitting element LD emitting light having a certain luminance corresponding to the amount of current it receives.

The pixel drive circuit PCij may include first to sixth transistors T1, T2, T3, T4, T5, and T6 and capacitors Cst and Chold.

The pixel PXij according to an embodiment of the present disclosure may be referred to as having a 6T2C structure.

In the present disclosure, the first transistor T1 is an N-type transistor. At least one of the second to sixth transistors T2, T3, T4, T5, and T6 is a P-type transistor. The remaining transistors other than at least one of the second to sixth transistors T2, T3, T4, T5, and T6 may be N-type transistors. The first transistor T1 may include an oxide semiconductor as a semiconductor layer. At least one of the second to sixth transistors T2, T3, T4, T5, and T6 may include a silicon semiconductor as a semiconductor layer, and the remaining transistors may include an oxide semiconductor as a semiconductor layer. For example, the silicon semiconductor may include amorphous silicon, low-temperature polycrystalline silicon, or crystalline silicon. However, the semiconductor layer of each of the transistors is not limited thereto.

The scan lines GCLi, GWLi, and GRLi may transfer scan signals GC, GW, and GR, respectively, and the light emission control lines EML1i and EML2i may transfer light emission signals EM1 and EM2, respectively. The data line DLj may transfer the data signal Vdata. The data signal Vdata may have a voltage level corresponding to the image signal RGB (refer to FIG. 1) that is input to the display device DD (refer to FIG. 1).

A first power line PL1 may provide the first power ELVDD. A second power line PL2 may provide the second power ELVSS. The second power ELVSS may have a lower voltage level than the first power ELVDD. A reference voltage line VL1 may provide the reference voltage Vref. A first initialization voltage line VL2 may provide the first initialization voltage Vcint.

The light emitting element LD may be connected between the first power line PL1 through which the first power ELVDD is provided and a first node N1. The light emitting element LD may include an anode AE and a cathode CE. The anode AE may be directly connected with the first power line PL1. The cathode CE may be electrically connected with the second power line PL2 via the fifth transistor T5, the first transistor T1, and the sixth transistor T6.

When the light emitting element LD is an organic light emitting element, the light emitting element LD may further include an organic layer disposed between the anode AE and the cathode CE. The cathode CE of the light emitting element LD may be connected to the pixel drive circuit PCij through the first node N1. The light emitting element LD may emit light in proportion to the drive current Id flowing through the first transistor T1 of the pixel drive circuit PCij.

The first transistor T1 may include a first electrode electrically connected with the first node N1 via the fifth transistor T5, a second electrode electrically connected with a second node N2, and a gate electrode (e.g., a front gate electrode) electrically connected with a third node N3. The first transistor T1 may be referred to as a drive transistor. In an embodiment of the present disclosure, the first transistor T1 may further include a back gate electrode. The back gate electrode of the first transistor T1 may be connected to the second electrode of the first transistor T1. However, embodiments are not limited thereto. For example, the back gate electrode of the first transistor T1 may be omitted.

According to the present disclosure, the first transistor T1 is an N-type transistor. The cathode CE of the light emitting element LD may be connected to the drain (or, the first electrode) of the first transistor T1. In this case, the voltage of the source (or, second electrode) terminal of the first transistor T1 should not be shifted even though the light emitting element LD becomes degraded. That is, the gate-source voltage Vgs of the first transistor T1 should not be changed even though the light emitting element LD becomes degraded. Accordingly, even though the amount of time that the pixel PX is used increases, the range of change in the amount of current flowing through the first transistor T1 may be decreased so that an after-image defect (or, a long-term after-image defect) of the display panel DP (refer to FIG. 1) may be reduced and the lifetime of the display panel DP (refer to FIG. 1) may be enhanced. Thus, a pixel PXij that enables enhanced display quality and a display device DD (refer to FIG. 1) including the same may be provided.

The second transistor T2 may include a first electrode electrically connected with the data line DLj through which the data signal Vdata is provided, a second electrode electrically connected with the third node N3, and a gate electrode that receives the scan signal GW. The gate electrode of the second transistor T2 may be connected with the write scan line GWLi.

The third transistor T3 may include a first electrode electrically connected with the first initialization voltage line VL2, a second electrode electrically connected with the first node N1, and a gate electrode that receives the compensation scan signal GC. The gate electrode of the third transistor T3 may be connected with the compensation scan line GCLi.

The fourth transistor T4 may include a first electrode electrically connected with the reference voltage line VL1 through which the reference voltage Vref is provided, a second electrode electrically connected with the third node N3, and a gate electrode that receives the initialization scan signal GR. The gate electrode of the fourth transistor T4 may be connected with the initialization scan line GRLi.

The fifth transistor T5 may include a first electrode electrically connected with the first node N1, a second electrode electrically connected with the first electrode of the first transistor T1, and a gate electrode that receives the first light emission signal EM1. The gate electrode of the fifth transistor T5 may be connected with the first light emission control line EML1i. The fifth transistor T5 may be referred to as a first light emission control transistor.

The sixth transistor T6 may include a first electrode electrically connected with the second node N2, a second electrode electrically connected with the second power line PL2 through which the second power ELVSS is provided, and a gate electrode that receives the second light emission signal EM2. The gate electrode of the sixth transistor T6 may be connected with the second light emission control line EML2i. The sixth transistor T6 may be referred to as a second light emission control transistor.

According to an embodiment of the present disclosure, each of the second to sixth transistors T2, T3, T4, T5, and T6 is a P-type transistor. That is, the second to sixth transistors T2, T3, T4, T5, and T6 corresponding to switching transistors other than the drive transistor are all P-type transistors. In particular, when the third transistor T3 electrically connected to the first initialization voltage line VL2 through which the first initialization voltage Vcint is provided and the fifth transistor T5 electrically connected to the first power line PL1 through which the first power ELVDD is provided are P-type transistors, the gate high voltages of the third transistor T3 and the fifth transistor T5 may be set to be lower than those when the third transistor T3 and the fifth transistor T5 are N-type transistors. That is, the high levels of the compensation scan signal GC and the first light emission signal EM1 may be set to be low. The high level of the compensation scan signal GC may be less than or equal to 10V. The high level of the first light emission signal EM1 may be less than or equal to 10V. Thus, a pixel PXij with reduced power consumption and the display device DD (refer to FIG. 1) including the same may be provided.

The first capacitor Cst may be connected between the second node N2 and the third node N3. The second capacitor Chold may be connected between the second node N2 and the second power line PL2.

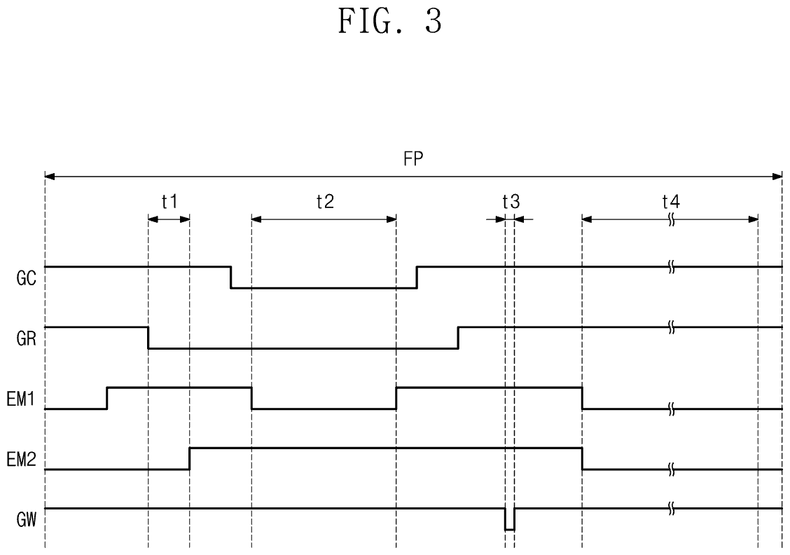

FIG. 3 is a timing chart for explaining an operation of the pixel PXij of FIG. 2 according to an embodiment of the present disclosure.

Referring to FIGS. 2 and 3, the display panel DP (refer to FIG. 1) may operate in units of frame periods FP to display an image. One frame period FP may include first to fourth periods t1, t2, t3, and t4. The first to third periods t1, t2, and t3 may be referred to as non-light emission periods, and the fourth period t4 may be referred to as a light emission period.

In the first period t1, the initialization scan signal GR and the second light emission signal EM2 may have an active level. The active level of each of the initialization scan signal GR and the second light emission signal EM2 may be a low level.

In the first period t1, the compensation scan signal GC, the first light emission signal EM1, and the scan signal GW may have an inactive level. The inactive level of each of the compensation scan signal GC, the first light emission signal EM1, and the scan signal GW may be a high level.

The fourth transistor T4 may be turned on in response to the initialization scan signal GR. The reference voltage Vref may be provided to the third node N3 through the fourth transistor T4.

During the first period t1, the gate electrode of the first transistor T1 may be initialized to the reference voltage Vref. That is, the voltage of the third node N3 may be changed from the data signal Vdata of the previous frame period to the reference voltage Vref.

The sixth transistor T6 may be turned on in response to the second light emission signal EM2. The second power ELVSS may be provided to the second node N2 through the sixth transistor T6.

During the first period t1, the source of the first transistor T1 may be initialized to the second power ELVSS. The pixel PXij may initialize the source of the first transistor T1 through the second power ELVSS without using a separate initialization voltage.

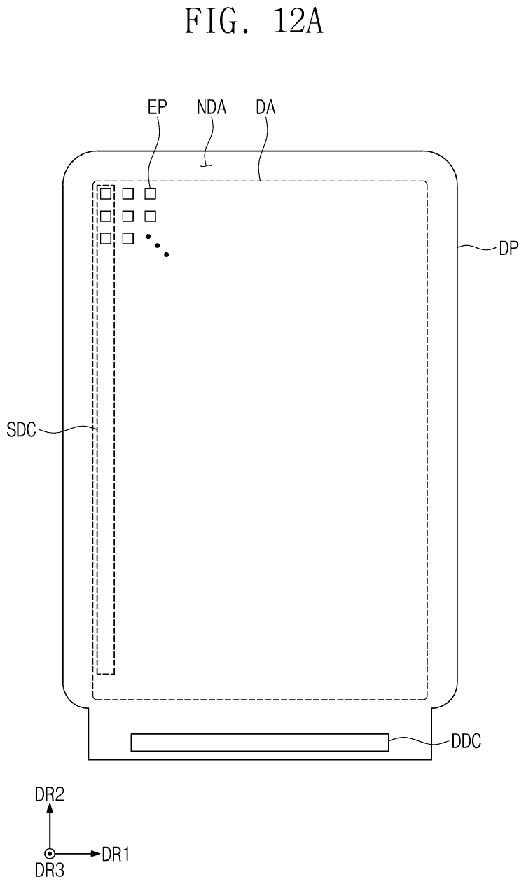

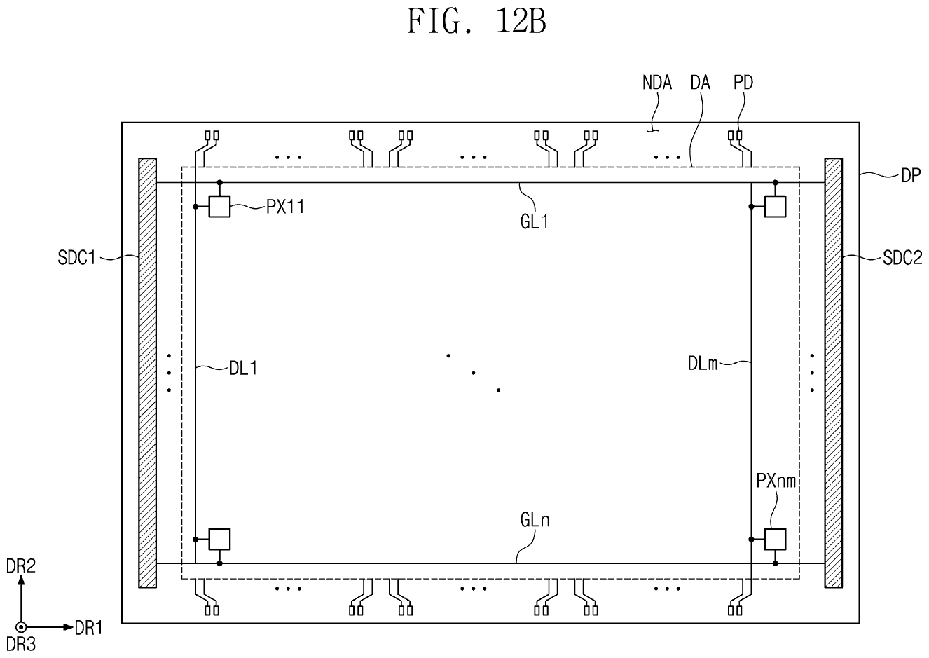

According to an embodiment of the present disclosure, the voltage generator 300 (refer to FIG. 1) does not include a separate power line for supplying an initialization voltage to the second node N2. Accordingly, the area of the non-display area NDA (refer to FIG. 12A) may be decreased. In addition, the number of power lines included in the pixel PXij may be decreased. When the number of power lines is decreased, a gap or spacing between lines included in the pixel PXij may be increased. Accordingly, signal interference between the lines may be reduced. Thus, a pixel PXij and a display device DD (refer to FIG. 1) including the pixel PXij enabling enhanced display quality may be provided.

The first period t1 may be referred to as an initialization period.

In the second period t2, the compensation scan signal GC, the initialization scan signal GR, and the first light emission signal EM1 may have an active level. The active level of each of the compensation scan signal GC, the initialization scan signal GR, and the first light emission signal EM1 may be a low level.

In the second period t2, the second light emission signal EM2 and the scan signal GW may have an inactive level. The inactive level of each of the second light emission signal EM2 and the scan signal GW may be a high level.

The fourth transistor T4 may be turned on in response to the initialization scan signal GR. The reference voltage Vref may be provided to the third node N3 through the fourth transistor T4.

The third transistor T3 may be turned on in response to the compensation scan signal GC. The fifth transistor T5 may be turned on in response to the first light emission signal EM1. The first transistor T1 may be turned on in response to the reference voltage Vref provided to the gate electrode.

As the third transistor T3 and the fifth transistor T5 are turned on, the first transistor T1 may operate as a source follower. A voltage equal to the reference Vref minus the threshold voltage Vth of the first transistor T1 may be provided to the second node N2, which corresponds to the source of the first transistor T1. That is, the voltage Vref-Vth may be provided to the source of the first transistor T1.

The second capacitor Chold may be connected with the second node N2. One electrode of the second capacitor Chold may be connected to the second power line PL2 that receives the second power ELVSS, and an opposite electrode of the second capacitor Chold may be connected to the second node N2. The second capacitor Chold may store charges corresponding to a voltage difference between the second node N2 and the second power supply voltage ELVSS, that is (Vref-Vth)-ELVSS. The second capacitor Chold may be referred to as a hold capacitor. The second capacitor Chold may have a higher storage capacity than the first capacitor Cst. The second capacitor Chold may minimize variations in the voltage of the second node N2 in response to changes in the voltage of the third node N3.

The second period t2 may be referred to as a compensation period.

In the third period t3, the scan signal GW may have an active level. The active level of the scan signal GW may be a low level.

In the third period t3, the compensation scan signal GC, the initialization scan signal GR, the first light emission signal EM1, and the second light emission signal EM2 may have an inactive level. The inactive level of each of the compensation scan signal GC, the initialization scan signal GR, the first light emission signal EM1, and the second light emission signal EM2 may be a high level.

The second transistor T2 may be turned on in response to the scan signal GW. The data signal Vdata provided through the data line DLj may be provided to the third node N3.

The first capacitor Cst may be disposed between the second node N2 and the third node N3. The first capacitor Cst may store a voltage corresponding to the difference between the voltages of the second node N2 and the third node N3. The voltage level of one end of the first capacitor Cst, that is, the third node N3 may be changed to the voltage level of the data signal Vdata. In this case, the voltage level of an opposite end of the first capacitor Cst, that is, the second node N2 may be a voltage level of Vref-Vth. The first capacitor Cst may store charges corresponding to a voltage difference Vdata-(Vref-Vth) between the third node N3 and the second node N2. The first capacitor Cst may be referred to as a storage capacitor.

The third period t3 may be referred to as a write period.

In the fourth period t4, the first light emission signal EM1 and the second light emission signal EM2 may have an active level. The active level of each of the first light emission signal EM1 and the second light emission signal EM2 may be a low level.

In the fourth period t4, the compensation scan signal GC, the initialization scan signal GR, and the scan signal GW may have an inactive level. The inactive level of each of the compensation scan signal GC, the initialization scan signal GR, and the scan signal GW may be a high level.

The fifth transistor T5 may be turned on in response to the first light emission signal EM1. The sixth transistor T6 may be turned on in response to the second light emission signal EM2.

As the fifth transistor T5 and the sixth transistor T6 are turned on, a current path may be formed from the first power line PL1 to the light emitting element LD, the fifth transistor T5, the first transistor T1, the sixth transistor T6, and the second power line PL2. That is, the drive current Id may flow to the second power ELVSS via the first power line PL1, the light emitting element LD, the fifth transistor T5, the first transistor T1, the sixth transistor T6, and the second power line PL2.

The voltage value of the second power ELVSS may have a value less than the reference voltage Vref reduced by the threshold voltage Vth of the first transistor T1.

Unlike the present disclosure, if the second power supply voltage ELVSS exceeds the reference voltage Vref minus the threshold voltage Vth of the first transistor T1, an unintended current may be formed. However, according to the present disclosure, the second power ELVSS may be set to a value less than the reference voltage Vref minus the threshold voltage Vth of the first transistor T1, allowing a current path to be reliably formed. The light emitting element LD may then more easily emit light. Thus, a pixel PXij and a display device DD (refer to FIG. 1) including the pixel PXij enabling enhanced display quality may be provided.

The data signals output from the data drive circuit 200 (refer to FIG. 1) of the display panel DP (refer to FIG. 1) may be written, and accordingly, the light emitting element LD may emit light. The drive current Id may be expressed by equations below.

$$Id = \frac{1}{2} \cdot μ \cdot Cox \cdot \frac{W}{L} {( Vgs - Vth )}^{2} \qquad [ EQ . 1 ]$$

$$Vgs = [ ( Vdata ) + ( ELVSS - ( Vref - Vth ) ) ] \qquad [ EQ . 2 ]$$

$$Id = \frac{1}{2} \cdot μ \cdot Cox \cdot {\frac{W}{L} [ ( Vdata + ELVSS - Vref + Vth ) - ELVSS - Vth ]}^{2} \qquad [ EQ . 3 ]$$

$$Id = \frac{1}{2} \cdot μ \cdot Cox \cdot \frac{W}{L} {( Vdata - Vref )}^{2} \qquad [ EQ . 4 ]$$

In the equations above, p may be a field effect mobility, Cox may be the capacitance of a gate insulating film, W/L may be the width and length of the first transistor T1, and Vgs may be the gate-source voltage of the first transistor T1. Here, p and Cox may be constants. Reorganization of Equation 3 (e.g., EQ. 3) obtained by substituting Equation 2 (e.g., EQ. 2) into Equation 1 (e.g., EQ. 1) may yield Equation 4 (e.g., EQ. 4).

The threshold voltage Vth of the first transistor T1 included in each of the pixels PX (refer to FIG. 1) may vary depending on the characteristics of the first transistor T1. However, according to the present disclosure, the threshold voltage Vth of the first transistor T1 should not affect the drive current Id flowing through the light emitting element LD during the time periods t1, t2, t3, and t4. Referring to Equation 4, the drive current Id flowing through the light emitting element LD in the fourth period t4 should not be affected by the threshold voltage Vth of the first transistor T1. The drive current Id flowing through the light emitting element LD may be proportional to the square of the difference between the data signal Vdata and the reference voltage Vref, regardless of the characteristics of the first transistor T1. Accordingly, the luminance of an image output from the display panel DP (refer to FIG. 1) may be uniformly maintained. Thus, a pixel PXij and a display device DD (refer to FIG. 1) including the pixel PXij enabling enhanced display quality may be provided.

Furthermore, the voltage level of the second power ELVSS in the second power line PL2 may be changed by a voltage drop phenomenon (referred to as IR Drop). However, according to the present disclosure, the second power ELVSS should not affect the drive current Id flowing through the light emitting element LD during the first to fourth time periods t1, t2, t3, and t4. Referring to Equation 4, the drive current Id flowing through the light emitting element LD in the fourth period t4 should not be affected by the second power ELVSS. The drive current Id may be proportional to the square of the difference between the data signal Vdata and the reference voltage Vref, regardless of the voltage value of the second power ELVSS. Accordingly, the luminance of an image output from the display panel DP (refer to FIG. 1) may be uniformly maintained. Thus, a pixel PXij and a display device DD (refer to FIG. 1) including the pixel PXij enabling enhanced display quality may be provided.

In addition, according to the present disclosure, the first transistor T1 may be an N-type transistor, and the cathode CE of the light emitting element LD may be electrically connected with the drain of the first transistor T1. In this case, the voltage of the source terminal of the first transistor T1 that affects the drive current Id should not change or be shifted even though the light emitting element LD becomes degraded. That is, the gate-source voltage Vgs of the first transistor T1 should not be changed even though the light emitting element LD becomes degraded. Accordingly, even though the usage time increases, the range of change in the amount of current flowing through the first transistor T1 may be decreased so that an after-image defect (or, a long-term after-image defect) of the display panel DP (refer to FIG. 1) may be reduced and the lifetime of the display panel DP (refer to FIG. 1) may be enhanced. Thus, a pixel PXij and a display device DD (refer to FIG. 1) including the pixel PXij enabling enhanced display quality may be provided.

The fourth period t4 may be referred to as a light emission period.

In an embodiment of the present disclosure, the voltage value of the first power ELVDD may be about 8.4V, and the voltage value of the second power ELVSS may be about 0V. The voltage value of the reference voltage Vref may be about 2.7V. The voltage value of the first initialization voltage Vcint may be equal to the voltage value of the first power ELVDD. The voltage value of the first initialization voltage Vcint may be about 8.4V. The voltage value of the data signal Vdata may range from about 2V to about 7V. The threshold voltage Vth of an N-type transistor may be about 0V, a threshold voltage Vth of a P-type transistor may be about −2V, and a margin value for Vth may be set to about 2V.

The low level or activation level of each of the compensation scan signal GC and the first light emission signal EM1 may be about 4.4V, and the high level or inactivation level of each of the compensation scan signal GC and the first light emission signal EM1 may be about 8.4V. A turn-on voltage for turning on the third transistor T3 and the fifth transistor T5 may be about 4.4V, and a turn-off voltage for turning off the third transistor T3 and the fifth transistor T5 may be about 8.4V.

The low level or activation level of the scan signal GW may be −2V, and the high level or inactivation level of the scan signal GW may be 7V. A turn-on voltage for turning on the second transistor T2 may be about −2V, and a turn-off voltage for turning off the second transistor T2 may be about 7V.

The low level or activation level of the initialization scan signal GR may be −1.3V, and the high level or inactivation level of the initialization scan signal GR may be 2.7V. A turn-on voltage for turning on the fourth transistor T4 may be about −1.3V, and a turn-off voltage for turning off the fourth transistor T4 may be about 2.7V.

The low level or activation level of the second light emission signal EM2 may be −3V, and the high level or inactivation level of the second light emission signal EM2 may be 1V. A turn-on voltage for turning on the sixth transistor T6 may be about −3V, and a turn-off voltage for turning off the sixth transistor T6 may be about 1V.

The maximum voltage value required to turn on and off the transistors in the pixel drive circuit PCij (or, the maximum voltage value of the gate high voltage of the transistors) may be about 8.4V, and the minimum voltage value (or, the minimum voltage value of the gate low voltage of the transistors) may be about −3V. In this embodiment, the maximum voltage value may be determined by the inactivation level that is the high level of each of the compensation scan signal GC and the first light emission signal EM1, and the minimum voltage value may be determined by the activation level that is the low level of the second light emission signal EM2. The voltage difference between the maximum voltage value and the minimum voltage value may be about 11.4V.

In contrast to the present disclosure, if the second to sixth transistors T2, T3, T4, T5, and T6 are all implemented with an N-type transistor, the active level of each of the compensation scan signal GC, the initialization scan signal GR, the first light emission signal EM1, the second light emission signal EM2, and the scan signal GW would need to be a high level, and the inactive level of each of the compensation scan signal GC, the initialization scan signal GR, the first light emission signal EM1, the second light emission signal EM2, and the scan signal GW would need to be a low level. In addition, a turn-on voltage for turning on each of the second to sixth transistors T2, T3, T4, T5, and T6 would need to be a high level of a corresponding signal. In this case, the low level or inactive level of each of the compensation scan signal GC and the first light emission signal EM1 may be about 6.4V, and the high level or active level of each of the compensation scan signal GC and the first light emission signal EM1 may be about 10.4V. The low level or inactivation level of the scan signal GW may be 0V, and the high level or activation level of the scan signal GW may be 9V. The low level or inactivation level of the initialization scan signal GR may be 0.7V, and the high level or activation level of the initialization scan signal GR may be 4.7V. The low level or inactivation level of the second light emission signal EM2 may be −2V, and the high level or activation level of the second light emission signal EM2 may be 3V. In this case, the maximum voltage value required to turn on and off the transistors in the pixel drive circuit PCij may be about 10.4V, and the minimum voltage value may be about −2V. The voltage difference between the maximum voltage value and the minimum voltage value may be about 12.4V.

That is, when each of the third transistor T3 and the fifth transistor T5 is implemented with an N-type transistor, a turn-on voltage for turning on each of the third transistor T3 and the fifth transistor T5 may need to be set higher than 8.4V. In other words, the activation level that is the high level of the compensation scan signal GC and the first light emission signal EM1 may need to be set higher than 8.4V, and the maximum voltage value required to turn on and off the transistors in the pixel drive circuit PCij may also need to be increased.

Meanwhile, when the sixth transistor T6 is implemented with an N-type transistor, a turn-off voltage for turning off the sixth transistor T6 may be set to be higher than −2V. That is, the inactivation level that is the low level of the second light emission signal EM2 may be set to be higher than −2V, and the minimum voltage value required to turn on and off the transistors in the pixel drive circuit PCij may also be increased. However, since the degree to which the low level of the second light emission signal EM2 is increased is lower than the degree to which the high level of the compensation scan signal GC is increased, when the third, fifth, and sixth transistors T3, T5, and T6 are implemented with an N-type transistor, the voltage difference between the maximum voltage value and the minimum voltage value may be increased, as compared with when the third, fifth, and sixth transistors T3, T5, and T6 are implemented with a P-type transistor.

Accordingly, according to this embodiment, the voltage difference between the maximum voltage value and the minimum voltage value may be decreased by implementing the second to sixth transistors T2, T3, T4, T5, and T6 with a P-type transistor. Since power consumption is proportional to the square of the voltage difference between the maximum voltage value and the minimum voltage value, a pixel PXij with reduced power consumption and a display device DD (refer to FIG. 1) including the same may be provided.

Additionally, according to an embodiment of the present disclosure, the first power ELVDD may be driven even though the first power ELVDD has a voltage value lower than 8.4V. That is, the voltage value of the first power ELVDD may be lower than 8.4V. For example, when the voltage value of the second power ELVSS is about 0V, the voltage value of the reference voltage Vref is about 2.7V, and the voltage value of the data signal Vdata ranges from about 2V to about 7V, the voltage value of the first power ELVDD may be set to about 7V. The voltage value of the first initialization voltage Vcint may be equal to the voltage value of the first power ELVDD, and the voltage value of the first initialization voltage Vcint may also be set to about 7V. In this case, the low level or activation level of each of the compensation scan signal GC and the first light emission signal EM1 may be about 3V, and the high level or inactivation level of each of the compensation scan signal GC and the first light emission signal EM1 may be about 7V. Accordingly, the maximum voltage value required to turn on and off the transistors in the pixel drive circuit PCij may be decreased to about 7V, and the voltage difference between the maximum voltage value and the minimum voltage value may be deceased to about 10V. Since power consumption is proportional to the square of the voltage difference between the maximum voltage value and the minimum voltage value, the pixel PXij with further reduced power consumption and the display device DD (refer to FIG. 1) including the same may be provided.

Meanwhile, the high and low level voltage values of each of the signals may vary depending on the settings of the first power ELVDD, the second power ELVSS, the reference voltage Vref, and the first initialization voltage Vcint. These levels may also depend on the settings of the threshold voltage Vth values of each transistor and a margin value applied to account for variations in the threshold voltage Vth of each transistor.

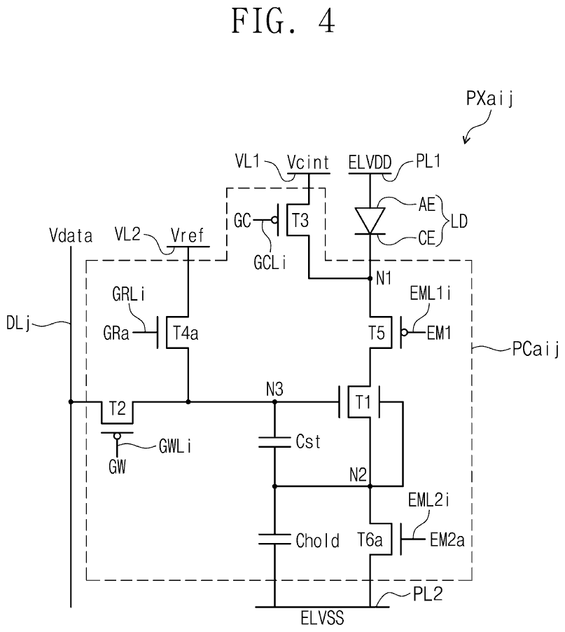

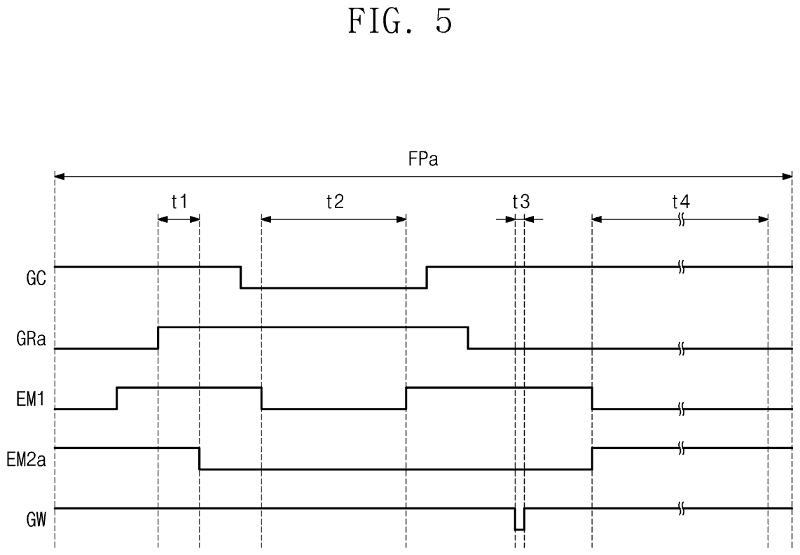

FIG. 4 is a circuit diagram of a pixel PXaij according to an embodiment of the present disclosure. FIG. 5 is a timing chart for explaining an operation of the pixel PXaij of FIG. 4 according to an embodiment of the present disclosure.

Referring to FIG. 4, the pixel PXaij may include a light emitting element LD and a pixel drive circuit PCaij. The pixel drive circuit PCaij may include first to sixth transistors T1, T2, T3, T4a, T5, and T6a and capacitors Cst and Chold.

The first transistor T1 is an N-type transistor. According to an embodiment of the present disclosure, each of the second, third, and fifth transistors T2, T3, and T5 is a P-type transistor, and each of the fourth and sixth transistors T4a and T6a is an N-type transistor. That is, some of the switching transistors are implemented with a P-type transistor, and the other switching transistors are implemented with an N-type transistor.

Referring to FIGS. 4 and 5, one frame period FPa may include first to fourth periods t1, t2, t3, and t4.

In the case of a scan signal GW provided to the gate electrode of the second transistor T2, an active level may be a low level, and an inactive level may be a high level. In the case of a compensation scan signal GC provided to the gate electrode of the third transistor T3, an active level may be a low level, and an inactive level may be a high level. In the case of a first light emission signal EM1 provided to the gate electrode of the fifth transistor T5, an active level may be a low level, and an inactive level may be a high level.

In the case of an initialization scan signal GRa provided to the gate electrode of the fourth transistor T4a, an active level may be a high level, and an inactive level may be a low level. In the case of a second light emission signal EM2a provided to the gate electrode of the sixth transistor T6a, an active level may be a high level, and an inactive level may be a low level.

In the first period t1, the initialization scan signal GRa and the second light emission signal EM2a may have an active level, and the compensation scan signal GC, the first light emission signal EM1, and the scan signal GW may have an inactive level. The active level of each of the initialization scan signal GRa and the second light emission signal EM2a may be a high level. The inactive level of each of the compensation scan signal GC, the first light emission signal EM1, and the scan signal GW may be a high level.

In the second period t2, the compensation scan signal GC, the initialization scan signal GRa, and the first light emission signal EM1 may have an active level, and the second light emission signal EM2a, and the scan signal GW may have an inactive level. The active level of each of the compensation scan signal GC and the first light emission signal EM1 may be a low level, and the active level of the initialization scan signal GRa may be a high level. The inactive level of the scan signal GW may be a high level, and the inactive level of the second light emission signal EM2a may be a low level.

In the third period t3, the scan signal GW may have an active level, and the compensation scan signal GC, the initialization scan signal GRa, the first light emission signal EM1, and the second light emission signal EM2a may have an inactive level. The active level of the scan signal GW may be a low level. The inactive level of each of the compensation scan signal GC and the first light emission signal EM1 may be a high level, and the inactive level of each of the initialization scan signal GRa and the second light emission signal EM2a may be a low level.

In the fourth period t4, the first light emission signal EM1 and the second light emission signal EM2a may have an active level, and the compensation scan signal GC, the initialization scan signal GRa, and the scan signal GW may have an inactive level. The active level of the first light emission signal EM1 may be a low level, and the active level of the second light emission signal EM2a may be a high level. The inactive level of each of the compensation scan signal GC and the scan signal GW may be a high level, and the inactive level of the initialization scan signal GRa may be a low level.

In an embodiment of the present disclosure, the voltage value of the first power ELVDD may be about 7V, and the voltage value of the second power ELVSS may be about 0V. The voltage value of the reference voltage Vref may be about 2.7V. In an embodiment, the voltage value of the first initialization voltage Vcint is equal to the voltage value of the first power ELVDD. The voltage value of the first initialization voltage Vcint may be about 7V. The voltage value of the data signal Vdata may range from about 2V to about 7V.

The low level or activation level of each of the compensation scan signal GC and the first light emission signal EM1 may be about 3V, and the high level or inactivation level of each of the compensation scan signal GC and the first light emission signal EM1 may be about 7V. A turn-on voltage for turning on the third transistor T3 and the fifth transistor T5 may be about 3V, and a turn-off voltage for turning off the third transistor T3 and the fifth transistor T5 may be about 7V.

The low level or activation level of the scan signal GW may be −2V, and the high level or inactivation level of the scan signal GW may be 7V. A turn-on voltage for turning on the second transistor T2 may be about −2V, and a turn-off voltage for turning off the second transistor T2 may be about 7V.

The low level or inactivation level of the initialization scan signal GRa may be 0.7V, and the high level or activation level of the initialization scan signal GRa may be 4.7V. A turn-on voltage for turning on the fourth transistor T4a may be about 4.7V, and a turn-off voltage for turning off the fourth transistor T4a may be about 0.7V.

The low level or inactivation level of the second light emission signal EM2a may be −2V, and the high level or activation level of the second light emission signal EM2a may be 3V. A turn-on voltage for turning on the sixth transistor T6a may be about 3V, and a turn-off voltage for turning off the sixth transistor T6a may be about −2V.

The maximum voltage value required to turn on and off the transistors in the pixel drive circuit PCaij may be about 7V, and the minimum voltage value may be about −2V. The maximum voltage value may be determined by the inactivation level that is the high level of each of the compensation scan signal GC and the first light emission signal EM1, and the minimum voltage value may be determined by the inactivation level that is the low level of the second light emission signal EM2a. The voltage difference between the maximum voltage value and the minimum voltage value may be about 9V. When the first, fourth, and sixth transistors T1, T4a, and T6a are implemented with an N-type transistor and the second, third, and fifth transistors T2, T3, and T5 are implemented with a P-type transistor, the voltage value of the first power ELVDD may be reduced. In this configuration, the maximum voltage value may be lowered without changing the minimum voltage value, as compared to a configuration in which the first to sixth transistors T1, T2, T3, T4, T5, and T6 are all implemented as N-type transistors. Accordingly, the voltage difference between the maximum voltage value and the minimum voltage value may be further decreased, and the pixel PXaij with further reduced power consumption and the display device DD (refer to FIG. 1) including the same may be provided.

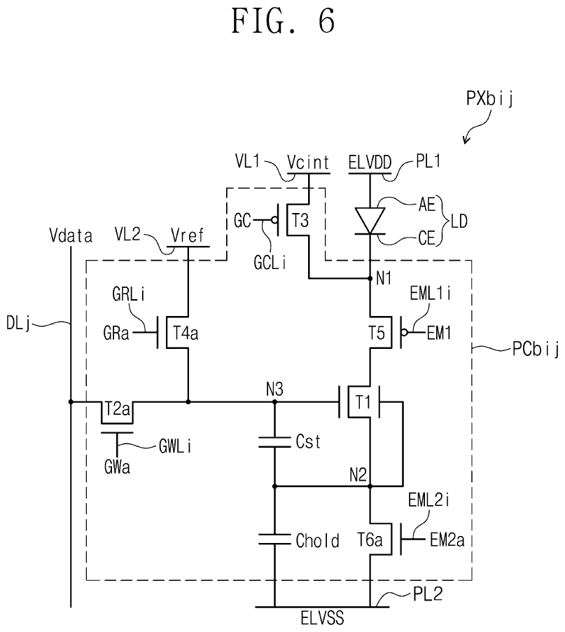

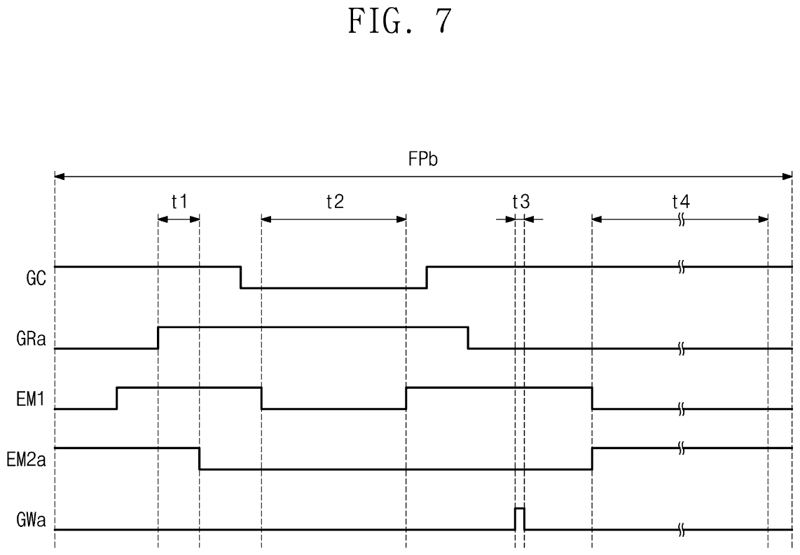

FIG. 6 is a circuit diagram of a pixel PXbij according to an embodiment of the present disclosure. FIG. 7 is a timing chart for explaining an operation of the pixel PXbij of FIG. 6 according to an embodiment of the present disclosure.

Referring to FIG. 6, the pixel PXbij may include a light emitting element LD and a pixel drive circuit PCbij. The pixel drive circuit PCbij may include first to sixth transistors T1, T2a, T3, T4a, T5, and T6a and capacitors Cst and Chold.

The first transistor T1 is an N-type transistor. According to an embodiment of the present disclosure, each of the third transistor T3 and the fifth transistor T5 is a P-type transistor, and each of the second transistor T2a, the fourth transistor T4a, and the sixth transistor T6a is an N-type transistor. That is, some of the switching transistors are implemented as P-type transistors, and the other switching transistors are implemented as N-type transistors.

In the case of a compensation scan signal GC provided to the gate electrode of the third transistor T3, an active level may be a low level, and an inactive level may be a high level. In the case of a first light emission signal EM1 provided to the gate electrode of the fifth transistor T5, an active level may be a low level, and an inactive level may be a high level.

In the case of a scan signal GWa provided to the gate electrode of the second transistor T2a, an active level may be a high level, and an inactive level may be a low level. In the case of an initialization scan signal GRa provided to the gate electrode of the fourth transistor T4a, an active level may be a high level, and an inactive level may be a low level. In the case of a second light emission signal EM2a provided to the gate electrode of the sixth transistor T6a, an active level may be a high level, and an inactive level may be a low level.

In the first period t1, the initialization scan signal GRa and the second light emission signal EM2a may have an active level, and the compensation scan signal GC, the first light emission signal EM1, and the scan signal GWa may have an inactive level. The active level of each of the initialization scan signal GRa and the second light emission signal EM2a may be a high level. The inactive level of each of the compensation scan signal GC and the first light emission signal EM1 may be a high level, and the inactive level of the scan signal GWa may be a low level.

In the second period t2, the compensation scan signal GC, the initialization scan signal GRa, and the first light emission signal EM1 may have an active level, and the second light emission signal EM2a, and the scan signal GWa may have an inactive level. The active level of each of the compensation scan signal GC and the first light emission signal EM1 may be a low level, and the active level of the initialization scan signal GRa may be a high level. The inactive level of each of the scan signal GWa and the second light emission signal EM2a may be a low level.

In the third period t3, the scan signal GWa may have an active level, and the compensation scan signal GC, the initialization scan signal GRa, the first light emission signal EM1, and the second light emission signal EM2a may have an inactive level. The active level of the scan signal GWa may be a high level. The inactive level of each of the compensation scan signal GC and the first light emission signal EM1 may be a high level, and the inactive level of each of the initialization scan signal GRa and the second light emission signal EM2a may be a low level.

In the fourth period t4, the first light emission signal EM1 and the second light emission signal EM2a may have an active level, and the compensation scan signal GC, the initialization scan signal GRa, and the scan signal GWa may have an inactive level. The active level of the first light emission signal EM1 may be a low level, and the active level of the second light emission signal EM2a may be a high level. The inactive level of the compensation scan signal GC may be a high level, and the inactive level of each of the initialization scan signal GRa and the scan signal GWa may be a low level.

In an embodiment of the present disclosure, the voltage value of the first power ELVDD may be about 7V, and the voltage value of the second power ELVSS may be about 0V. The voltage value of the reference voltage Vref may be about 2.7V. In an embodiment, the voltage value of the first initialization voltage Vcint is equal to the voltage value of the first power ELVDD. The voltage value of the first initialization voltage Vcint may be about 7V. The voltage value of the data signal Vdata may range from about 2V to about 7V. Vth of an N-type transistor may be about 0V, Vth of a P-type transistor may be about −2V, and a margin value for Vth may be set to about 2V.

The low level or activation level of each of the compensation scan signal GC and the first light emission signal EM1 may be about 3V, and the high level or inactivation level of each of the compensation scan signal GC and the first light emission signal EM1 may be about 7V. A turn-on voltage for turning on the third transistor T3 and the fifth transistor T5 may be about 3V, and a turn-off voltage for turning off the third transistor T3 and the fifth transistor T5 may be about 7V.

The low level or inactivation level of the scan signal GWa may be 0V, and the high level or activation level of the scan signal GWa may be 9V. A turn-on voltage for turning on the second transistor T2a may be about 9V, and a turn-off voltage for turning off the second transistor T2a may be about 0V.

The low level or inactivation level of the initialization scan signal GRa may be 0.7V, and the high level or activation level of the initialization scan signal GRa may be 4.7V. A turn-on voltage for turning on the fourth transistor T4a may be about 4.7V, and a turn-off voltage for turning off the fourth transistor T4a may be about 0.7V.

The low level or inactivation level of the second light emission signal EM2a may be −2V, and the high level or activation level of the second light emission signal EM2a may be 3V. A turn-on voltage for turning on the sixth transistor T6a may be about 3V, and a turn-off voltage for turning off the sixth transistor T6a may be about −2V.

The maximum voltage value required to turn on and off the transistors in the pixel drive circuit PCbij may be about 9V, and the minimum voltage value may be about −2V. The maximum voltage value may be determined by the active level that is the high level of the scan signal GWa, and the minimum voltage value may be determined by the inactive level that is the low level of the second light emission signal EM2a. The voltage difference between the maximum voltage value and the minimum voltage value may be about 11V. When the first, second, fourth, and sixth transistors T1, T2, T4a, and T6a are implemented with N-type transistors and the third and fifth transistors T3 and T5 are implemented with P-type transistors, the voltage value of the first power ELVDD may be reduced and the maximum voltage value may be lowered without changing the minimum voltage value, as compared with when the first to sixth transistors T1, T2, T3, T4, T5, and T6 are all implemented with N-type transistors. Accordingly, the voltage difference between the maximum voltage value and the minimum voltage value may be further decreased, and the pixel PXbij with further reduced power consumption and the display device DD (refer to FIG. 1) including the same may be provided.

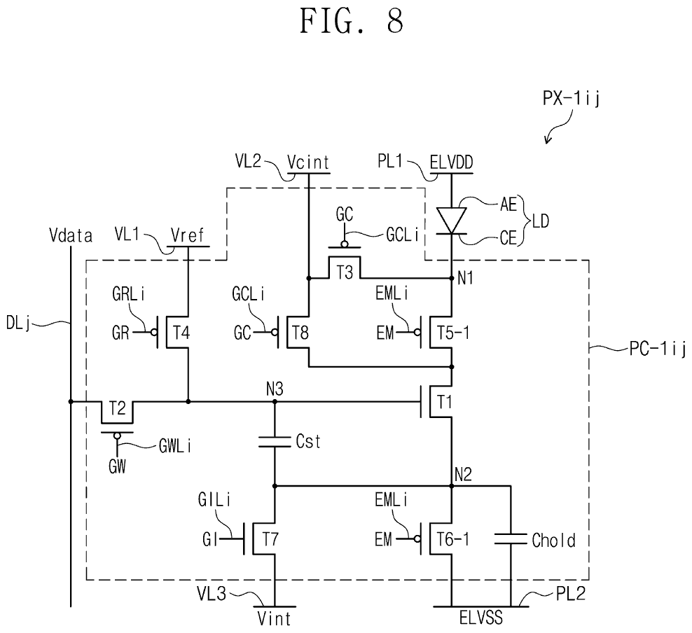

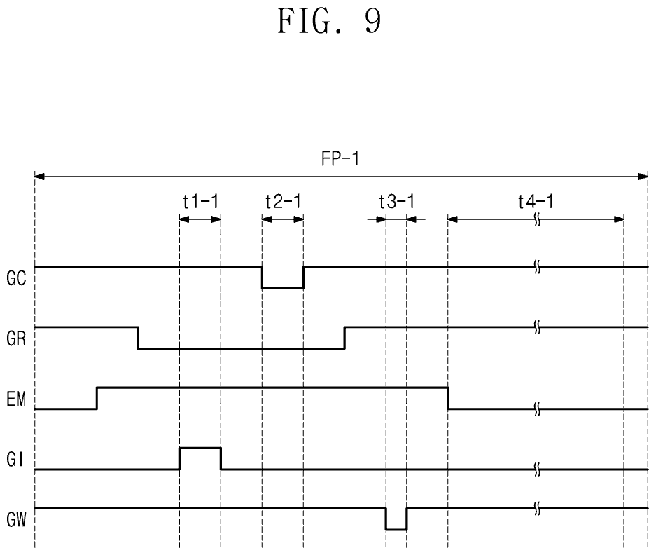

FIG. 8 is a circuit diagram of a pixel PX-1ij according to an embodiment of the present disclosure. FIG. 9 is a timing chart for explaining an operation of the pixel PX-1ij of FIG. 8 according to an embodiment of the present disclosure.

Referring to FIG. 8, the pixel PX-1ij may include a light emitting element LD and a pixel drive circuit PC-1ij. The pixel drive circuit PC-1ij may include first to eighth transistors T1, T2, T3, T4, T5-1, T6-1, T7, and T8 and capacitors Cst and Chold. That is, compared to the pixel drive circuit PCij described above with reference to FIG. 2, the pixel drive circuit PC-1ij further includes the seventh transistor T7 and the eighth transistor T8. The eighth transistor T8 may be referred to as a first initialization transistor, and the seventh transistor T7 may be referred to as a second initialization transistor.

The pixel PX-1ij according to an embodiment of the present disclosure may be referred to as having an 8T2C structure.

The first transistor T1 is an N-type transistor. In an embodiment of the present disclosure, at least one of the second to eighth transistors T2, T3, T4, T5-1, T6-1, T7, and T8 is a P-type transistor. The remaining transistors other than the at least one of the second to eighth transistors T2, T3, T4, T5-1, T6-1, T7, and T8 are N-type transistors. At least one of the second to eighth transistors T2, T3, T4, T5-1, T6-1, T7, and T8 may include a silicon semiconductor as a semiconductor layer, and the remaining transistors may include an oxide semiconductor as a semiconductor layer. For example, the silicon semiconductor may include amorphous silicon, low-temperature polycrystalline silicon, or crystalline silicon. However, the semiconductor layer of each of the transistors is not limited thereto.

According to an embodiment of the present disclosure, each of the second to sixth transistors T2, T3, T4, T5-1, and T6-1 and the eighth transistor T8 is a P-type transistor, and the seventh transistor T7 is an N-type transistor.

Each of the gate electrode of the fifth transistor T5-1 and the gate electrode of the sixth transistor T6-1 may be connected with the light emission scan line EMLi that receives a light emission signal EM. That is, the gate electrode of the fifth transistor T5-1 and the gate electrode of the sixth transistor T6-1 may receive the same signal.

The seventh transistor T7 may include a first electrode electrically connected to a second node N2, a second electrode electrically connected to a second initialization voltage line VL3 through which a second initialization voltage Vint is provided, and a gate electrode that receives an input scan signal GI. The gate electrode of the seventh transistor T7 may be connected with an input scan line GILi.

The eighth transistor T8 may include a first electrode connected to a first initialization voltage line VL2 that receives the first initialization voltage Vcint, a second electrode connected to the first electrode of the first transistor T1, and a gate electrode that receives a compensation scan signal GC. The gate electrode of the eighth transistor T8 may be connected with the compensation scan line GCLi.

In the case of the light emission signal EM provided to the gate electrode of each of the fifth transistor T5-1 and the sixth transistor T6-1, an active level may be a low level, and an inactive level may be a high level. In the case of the input scan signal GI provided to the gate electrode of the seventh transistor T7, an active level may be a high level, and an inactive level may be a low level.

According to an embodiment of the present disclosure, the third transistor T3 and the eighth transistor T8 electrically connected to the first initialization voltage line VL2 through which the first initialization voltage Vcint is provided and the fifth transistor T5 electrically connected to the first power line PL1 through which the first power ELVDD is provided is implemented with a P-type transistor, and thus the gate high voltage of each of the third, fifth, and eighth transistors T3, T5, and T8 may be set to be low. That is, the high level of each of the compensation scan signal GC and the light emission signal EM may be set to be low. The high level of the compensation scan signal GC may be less than or equal to 10V. The high level of the light emission signal EM may be less than or equal to 10V. Thus, the pixel PX-1ij with reduced power consumption and the display device DD (refer to FIG. 1) including the same may be provided.

Referring to FIGS. 8 and 9, the display panel DP (refer to FIG. 1) may operate in units of frame periods FP-1 to display an image. One frame period FP-1 may include first to fourth periods t1-1, t2-1, t3-1, and t4-1. The first to third periods t1-1, t2-1, and t3-1 may be referred to as non-light emission periods, and the fourth period t4-1 may be referred to as a light emission period.

In the first period t1-1, an initialization scan signal GR and the input scan signal GI may have an active level. The active level of the initialization scan signal GR may be a low level. The active level of the input scan signal GI may be a high level.

In the first period t1-1, the compensation scan signal GC, the light emission signal EM, and a scan signal GW may have an inactive level. The inactive level of each of the compensation scan signal GC, the light emission signal EM, and the scan signal GW may be a high level.

The fourth transistor T4 may be turned on in response to the initialization scan signal GR. The reference voltage Vref may be provided to a third node N3 through the fourth transistor T4.

During the first period t1-1, the gate electrode of the first transistor T1 may be initialized to the reference voltage Vref. That is, the voltage of the third node N3 may be changed from the data signal Vdata of the previous frame to the reference voltage Vref.

The seventh transistor T7 may be turned on in response to the input scan signal GI. The second initialization voltage Vint may be provided to the second node N2 through the seventh transistor T7.

According to the present disclosure, the second initialization voltage Vint provided from the voltage generator 300 (refer to FIG. 1) should not suffer from a voltage drop (IR drop). The second initialization voltage Vint may have a stable voltage value as compared to the second power ELVSS. Thus, the pixel PX-1ij and the display device DD (refer to FIG. 1) with enhanced reliability may be provided.

The voltage value of the second initialization voltage Vint may be set to a value less than the reference voltage Vref minus the threshold voltage Vth of the first transistor T1. For example, the voltage value of the second initialization voltage Vint may be less than or equal to the voltage value of the second power ELVSS.

The first period t1-1 may be referred to as an initialization period.

In the second period t2-1, the compensation scan signal GC and initialization scan signal GR may have an active level. The active level of each of the compensation scan signal GC and initialization scan signal GR may be a low level.

In the second period t2-1, the light emission signal EM, the input scan signal GI, and the scan signal GW may have an inactive level. The inactive level of each of the light emission signal EM and the scan signal GW may be a high level. The inactive level of the input scan signal GI may be a low level.

The fourth transistor T4 may be turned on in response to the initialization scan signal GR. The reference voltage Vref may be provided to the third node N3 through the fourth transistor T4.

The third transistor T3 may be turned on in response to the compensation scan signal GC. The eighth transistor T8 may be turned on in response to the input scan signal GI. The first transistor T1 may be turned on in response to the reference voltage Vref provided to the gate electrode.

As the eighth transistor T8 is turned on, the first transistor T1 may operate as a source follower. A voltage equal to the reference voltage Vref minus the threshold voltage Vth of the first transistor T1 may be applied to the second node N2, which serves as the source of the first transistor T1. That is, the voltage Vref-Vth may be provided to the source of the first transistor T1.

The second capacitor Chold may be connected with the second node N2. One electrode of the second capacitor Chold may be connected to the second power line PL2 that receives the second power ELVSS, and an opposite electrode of the second capacitor Chold may be connected to the second node N2. The second capacitor Chold may store charges corresponding to a voltage difference between the second node N2 and the second power supply voltage ELVSS, that is, (Vref−Vth)−ELVSS. The second capacitor Chold may be referred to as a hold capacitor. The second capacitor Chold may have a higher storage capacity than the first capacitor Cst. The second capacitor Chold may suppress variations in the voltage of the second node N2 in response to changes in the voltage of the third node N3.

The second period t2-1 may be referred to as a compensation period.

In the third period t3-1, the scan signal GW may have an active level. The active level of the scan signal GW may be a low level.

In the third period t3-1, the compensation scan signal GC, the initialization scan signal GR, the light emission signal EM, and the input scan signal GI may have an inactive level. The inactive level of each of the compensation scan signal GC, the initialization scan signal GR, and the light emission signal EM may be a high level. The inactive level of the input scan signal GI may be a low level.

The second transistor T2 may be turned on in response to the scan signal GW. The data signal Vdata provided through the data line DLj may be provided to the third node N3. The voltage level of an opposite end of the first capacitor Cst, that is, the second node N2 may be a voltage level of Vref−Vth. The first capacitor Cst may store charges corresponding to a voltage difference Vdata−(Vref−Vth) between the third node N3 and the second node N2.

The third period t3-1 may be referred to as a write period.

In the fourth period t4-1, the light emission signal EM may have an active level. The active level of the light emission signal EM may be a low level.

In the fourth period t4-1, the compensation scan signal GC, the initialization scan signal GR, the input scan signal GI, and the scan signal GW may have an inactive level. The inactive level of each of the compensation scan signal GC, the initialization scan signal GR, and the scan signal GW may be a high level. The inactive level of the input scan signal GI may be a low level.

The fifth transistor T5 and the sixth transistor T6 may be turned on in response to the light emission signal EM. The drive current Id may flow to the second power ELVSS via the first power line PL1, the light emitting element LD, the fifth transistor T5, the first transistor T1, the sixth transistor T6, and the second power line PL2. The voltage value of the second power ELVSS may be less than the reference voltage Vref minus the threshold voltage Vth of the first transistor T1.

According to the present disclosure, the threshold voltage Vth of the first transistor T1 should not affect the drive current Id flowing through the light emitting element LD by the first to fourth steps t1-1, t2-1, t3-1, and t4-1. Accordingly, the luminance of an image output from the display panel DP (refer to FIG. 1) may be uniformly maintained. Thus, the pixel PX-1ij and the display device DD (refer to FIG. 1) with enhanced display quality may be provided.

According to the present disclosure, the second power ELVSS should not affect the drive current Id flowing through the light emitting element LD by the first to fourth steps t1-1, t2-1, t3-1, and t4-1. Accordingly, the luminance of an image output from the display panel DP (refer to FIG. 1) may be uniformly maintained. Thus, the pixel PX-1ij and the display device DD (refer to FIG. 1) with enhanced display quality may be provided.

The fourth period t4-1 may be referred to as a light emission period.

In an embodiment of the present disclosure, the voltage value of the first power ELVDD may be about 8.4V, and the voltage value of the second power ELVSS may be about 0V. The voltage value of the reference voltage Vref may be about 2.7V. The voltage value of the first initialization voltage Vcint may be equal to the voltage value of the first power ELVDD. The voltage value of the first initialization voltage Vcint may be about 8.4V. The voltage value of the second initialization voltage Vint may be about −3V.

The maximum voltage value required to turn on and off the transistors in the pixel drive circuit PC-1ij may be about 10V, and the minimum voltage value may be about −6V. The voltage difference between the maximum voltage value and the minimum voltage value may be about 16V. The maximum voltage value may be determined by the inactivation level that is the high level of each of the compensation scan signal GC and the light emission signal EM. The minimum voltage value may be determined by the inactivation level that is the low level of the seventh transistor T7.

In contrast to the present disclosure, when the first to eighth transistors T1, T2, T3, T4, T5-1, T6-1, T7, and T8 are all implemented as N-type transistors, the active level of each of the compensation scan signal GC, the initialization scan signal GR, the light emission signal EM, the input scan signal GI, and the scan signal GW may be a high level, while the inactive level of each of the compensation scan signal GC, the initialization scan signal GR, the light emission signal EM, the input scan signal GI, and the scan signal GW may be a low level. In addition, a turn-on voltage for turning on each of the second to eighth transistors T2, T3, T4, T5-1, T6-1, T7, and T8 may need to be a high level of a corresponding signal. In this case, the maximum voltage value required to turn on and off the transistors in the pixel drive circuit PC-1ij may be about 15V, and the minimum voltage value may be about −6V. The voltage difference between the maximum voltage value and the minimum voltage value may be about 18V. The maximum voltage value may be determined by the activation level that is the high level of each of the compensation scan signal GC and the light emission signal EM. The minimum voltage value may be determined by the inactivation level that is the low level of the seventh transistor T7.

According to an embodiment of the present disclosure, the third, fifth, and eighth transistors T3, T5-1, and T8 are implemented as P-type transistors, and thus the gate high voltage may be lowered, as compared to when the third, fifth, and eighth transistors T3, T5-1, and T8 are implemented as N-type transistors. That is, the high level of each of the compensation scan signal GC and the light emission signal EM may be lowered, and the minimum voltage value required to turn on and off the transistors in the pixel drive circuit PC-1ij may be lowered. Accordingly, the voltage difference between the maximum voltage value and the minimum voltage value may be decreased, and the pixel PX-1ij with reduced power consumption and the display device DD (refer to FIG. 1) including the same may be provided.

Meanwhile, when the second to sixth transistors T2, T3, T4, T5-1, and T6-1 and the eighth transistor T8 are implemented as P-type transistors, the gate low voltage may also be lowered together, as compared with when the second to sixth transistors T2, T3, T4, T5-1, and T6-1 and the eighth transistor T8 are implemented as N-type transistors. However, when the second to sixth transistors T2, T3, T4, T5-1, and T6-1 and the eighth transistor T8 are implemented as P-type transistors, the degree to which the gate low voltage is lowered may be lower than the degree to which the gate high voltage is lowered. Accordingly, the voltage difference between the gate high voltage and the gate low voltage of the second to sixth transistors T2, T3, T4, T5-1, and T6-1 and the eighth transistor T8 may be decreased, and power consumption for the second to sixth transistors T2, T3, T4, T5-1, and T6-1 and the eighth transistor T8 may be reduced.

Additionally, according to an embodiment of the present disclosure, as compared with when the second, third, and fifth to eighth transistors T2, T3, T5-1, T6-1, T7, and T8 are implemented as N-type transistors, the first power ELVDD may be driven even though the first power ELVDD has a relatively low voltage value, when the second, third, and fifth to eighth transistors T2, T3, T5-1, T6-1, T7, and T8 are implemented as P-type transistors. In an embodiment, the voltage value of the first power ELVDD may be lower than 8.4V. Accordingly, the high-level voltage value of each of the compensation scan signal GC and the light emission signal EM may also be set to be low, and the minimum voltage value required to turn on and off the transistors in the pixel drive circuit PC-1ij may also be set to be low. Thus, the pixel PX-1ij with further reduced power consumption and the display device DD (refer to FIG. 1) including the same may be provided.

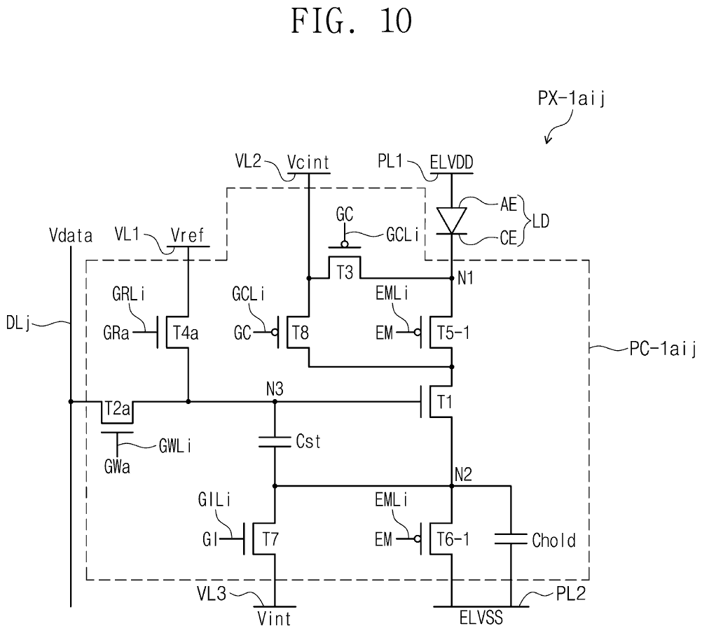

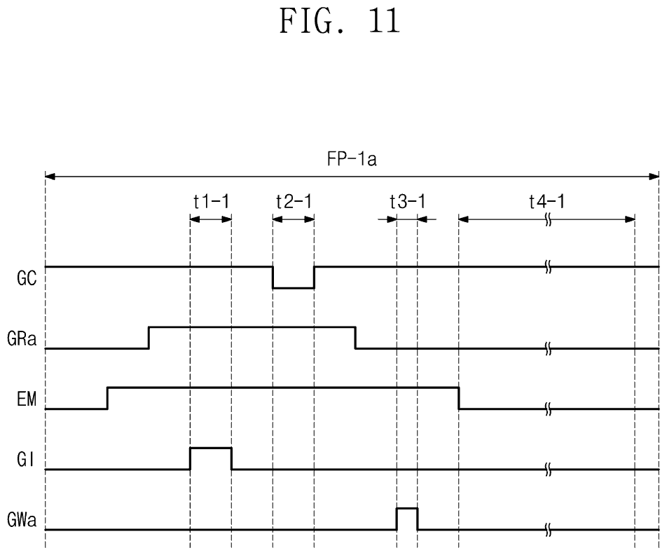

FIG. 10 is a circuit diagram of a pixel PX-1aij according to an embodiment of the present disclosure. FIG. 11 is a timing chart for explaining an operation of the pixel PX-1aij of FIG. 10 according to an embodiment of the present disclosure.

Referring to FIG. 10, the pixel PX-1aij may include a light emitting element LD and a pixel drive circuit PC-1aij. The pixel drive circuit PC-1aij may include first to eighth transistors T1, T2a, T3, T4a, T5-1, T6-1, T7, and T8 and capacitors Cst and Chold.

The first transistor T1 is an N-type transistor. According to an embodiment of the present disclosure, each of the third, fifth, sixth, and eighth transistors T3, T5-1, T6-1, and T8 is a P-type transistor, and each of the second, fourth, and seventh transistors T2a, T4a, and T7 is an N-type transistor.

Referring to FIGS. 10 and 11, one frame period FP-la may include first to fourth periods t1-1, t2-1, t3-1, and t4-1.

In the case of a compensation scan signal GC provided to the gate electrode of each of the third transistor T3 and the eighth transistor T8, an active level may be a low level, and an inactive level may be a high level. In the case of a light emission signal EM provided to the gate electrode of each of the fifth transistor T5-1 and the sixth transistor T6-1, an active level may be a low level, and an inactive level may be a high level.

In the case of a scan signal GWa provided to the gate electrode of the second transistor T2a, an active level may be a high level, and an inactive level may be a low level. In the case of an initialization scan signal GRa provided to the gate electrode of the fourth transistor T4a, an active level may be a high level, and an inactive level may be a low level. In the case of an input scan signal GI provided to the gate electrode of the seventh transistor T7, an active level may be a high level, and an inactive level may be a low level.

In the first period t1-1, the initialization scan signal GRa and the input scan signal GI may have an active level, and the compensation scan signal GC, the light emission signal EM, and the scan signal GWa may have an inactive level. The active level of each of the initialization scan signal GRa and the input scan signal GI may be a high level. The inactive level of each of the compensation scan signal GC and the light emission signal EM may be a high level, and the inactive level of the scan signal GWa may be a low level.

In the second period t2-1, the compensation scan signal GC and the initialization scan signal GRa may have an active level, and the light emission signal EM, the input scan signal GI, and the scan signal GWa may have an inactive level. The active level of the compensation scan signal GC may be a low level, and the active level of the initialization scan signal GRa may be a high level. The inactive level of the light emission signal EM may be a high level, and the inactive level of each of the input scan signal GI and the scan signal GWa may be a low level.

In the third period t3-1, the scan signal GWa may have an active level, and the compensation scan signal GC, the initialization scan signal GRa, the light emission signal EM, and the input scan signal GI may have an inactive level. The active level of the scan signal GWa may be a high level. The inactive level of each of the compensation scan signal GC and the light emission signal EM may be a high level, and the inactive level of each of the initialization scan signal GRa and the input scan signal GI may be a low level.

In the fourth period t4-1, the light emission signal EM may have an active level, and the compensation scan signal GC, the initialization scan signal GRa, the input scan signal GI, and the scan signal GWa may have an inactive level. The active level of the light emission signal EM may be a low level. The inactive level of the compensation scan signal GC may be a high level, and the inactive level of each of the initialization scan signal GRa, the input scan signal GI, and the scan signal GWa may be a low level.

According to this embodiment, by implementing the third, fifth, and eighth transistors T3, T5-1, and T8 as P-type transistors, a turn-on voltage for turning on each of the third, fifth, and eighth transistors T3, T5-1, and T8 may be lowered. Thus the voltage difference between the maximum voltage value and the minimum voltage value may be decreased. Additionally, according to an embodiment of the present disclosure, the first power ELVDD may be driven even though the first power ELVDD has a relatively low voltage value, so that the first power ELVDD may be set to be low. Accordingly, the turn-on voltage for turning on each of the third, fifth, and eighth transistors T3, T5-1, and T8 may be further lowered. Thus, the pixel PX-1aij with reduced power consumption and the display device DD (refer to FIG. 1) including the same may be provided.

FIGS. 12A and 12B are schematic plan views illustrating the display panel according to an embodiment of the present disclosure. In each of FIGS. 12A and 12B, some components are omitted. Hereinafter, the present disclosure will be described with reference to FIGS. 12A and 12B.

Referring to FIG. 12A, the display panel DP of an embodiment may be divided into a display area DA and a peripheral area (or, a non-display area) NDA. The display area DA may include a plurality of light emitting parts EP.

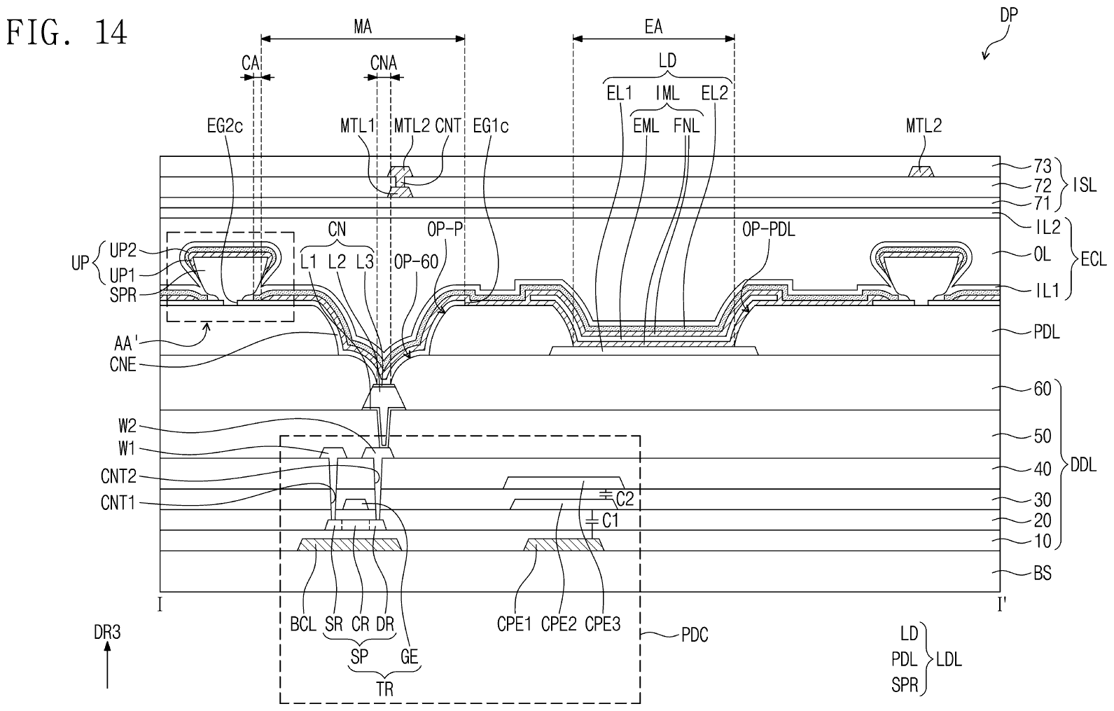

The light emitting parts EP may be areas where light is emitted by the pixels PX (refer to FIG. 1). Specifically, each of the light emitting parts EP may correspond to a light emitting opening OP-PDL (refer to FIG. 14) that will be described below. The light emitting opening OP-PDL may be referred to as an aperture or an opening.

The peripheral area NDA may be disposed adjacent to the display area DA. In this embodiment, the peripheral area NDA is illustrated as surrounding the periphery of the display area DA. However, the peripheral area NDA may be disposed on one side of the display area DA or may be omitted and is not limited to any one embodiment.

In this embodiment, a scan driver SDC and a data driver DDC may be mounted on the display panel DP. In an embodiment, the scan driver SDC may be disposed in the display area DA, and the data driver DDC may be disposed in the peripheral area NDA. The scan driver SDC, when viewed from above the plane, may overlap at least some of the plurality of light emitting parts EP disposed in the display area DA. Since the scan driver SDC is disposed in the display area DA, the area of the peripheral area NDA may be smaller than the area of a peripheral area of previous display panels in which a scan driver is disposed in the peripheral area, and a display device having a thin bezel may be more easily implemented.

Meanwhile, unlike that illustrated in FIG. 12A, the scan driver SDC may be implemented with two parts separated from each other. Two scan drivers SDC may be spaced apart from each other in the left-right direction with the center of the display area DA therebetween. Alternatively, the scan driver SDC may be implemented with two or more scan drivers. However, the present disclosure is not limited to any one embodiment.

Meanwhile, FIG. 12A illustrates an example of the display panel, and the data driver DDC may be disposed in the display area DA. In this case, some of the light emitting parts EP disposed in the display area DA may overlap the data driver DDC when viewed from above the plane.

In an embodiment, the data driver DDC may be provided in the form of a separate driver chip independent of the display panel DP and may be connected to the display panel DP. However, the data driver DDC may be formed using the same process as the scan driver SDC to implement the display panel DP and is not limited to any one embodiment.

As illustrated in FIG. 12B, the display panel DP may have a shape in which the length corresponding to the first direction DR1 is greater than the length corresponding to the second direction DR2. A plurality of pixels PX11 to PXnm arranged in n rows and m columns are disposed in the display area DA. In this embodiment, the display panel DP may include a plurality of scan drivers SDC1 and SDC2. The scan drivers SDC1 and SDC2 include the first scan driver SDC1 and the second scan driver SDC2 spaced apart from each other in the first direction DR1.

The first scan driver SDC1 may be connected with some of the scan lines GL1 to GLn, and the second scan driver SDC2 may be connected with the other scan lines. For example, the first scan driver SDC1 may be connected to odd-numbered scan lines among the scan lines GL1 to GLn, and the second scan driver SDC2 may be connected to even-numbered scan lines among the scan lines GL1 to GLn.

In FIG. 12B, for ease of description, pads PD of the data lines DL1 to DLm are illustrated. The pads PD may be defined at ends of the data lines DL1 to DLm. The data lines DL1 to DLm may be connected to the data driver DDC (refer to FIG. 12A) through the pads PD.

According to the present disclosure, the pads PD may be arranged in opposite regions of the peripheral area NDA spaced apart from each other with the display area DA therebetween. For example, some of the pads PD may be disposed on the upper side, that is, on one side adjacent to the first scan line GL1 among the scan lines GL1 to GLn, and the other pads may be disposed on the lower side, that is, on an opposite side adjacent to the last scan line GLn among the scan lines GL1 to GLn. In this embodiment, pads PD connected to odd-numbered data lines among the data lines DL1 to DLm may be disposed on the upper side, and pads PD connected to even-numbered data lines among the data lines DL1 to DLm may be disposed on the lower side.

The display panel DP may include a plurality of upper data drivers connected with the pads PD disposed on the upper side and/or a plurality of lower data drivers connected with the pads PD disposed on the lower side but is not limited thereto. For example, the display panel DP may include one upper data driver connected with the pads PD disposed on the upper side and/or one lower data driver connected with the pads PD disposed on the lower side. The pads PD according to an embodiment of the present disclosure may be disposed on only one side of the display panel DP and connected to a single data driver and are not limited to any one embodiment.

In addition, as described above with reference to FIG. 12A, the display panel DP in FIG. 12B may also include a scan driver and/or a data driver disposed in the display area DA. Accordingly, some of the light emitting parts disposed in the display area DA may overlap the scan driver and/or the data driver when viewed from above the plane.

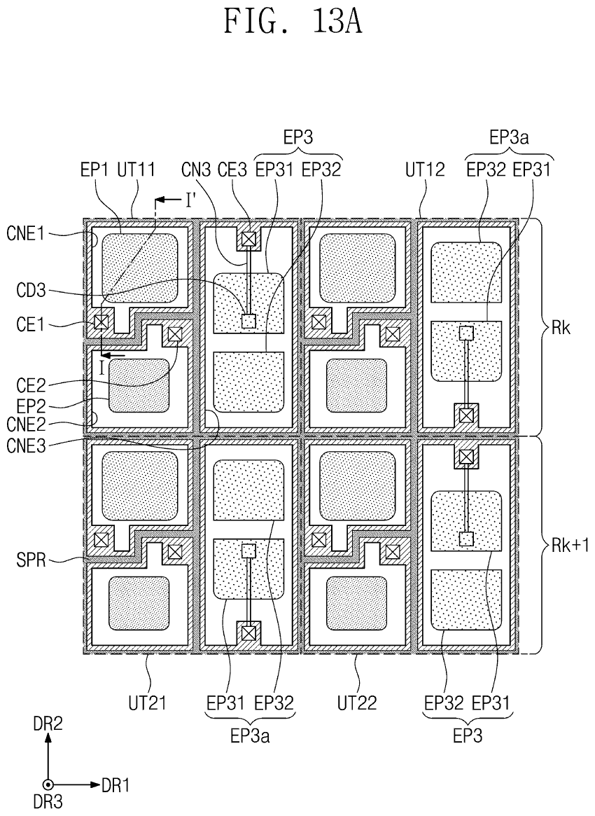

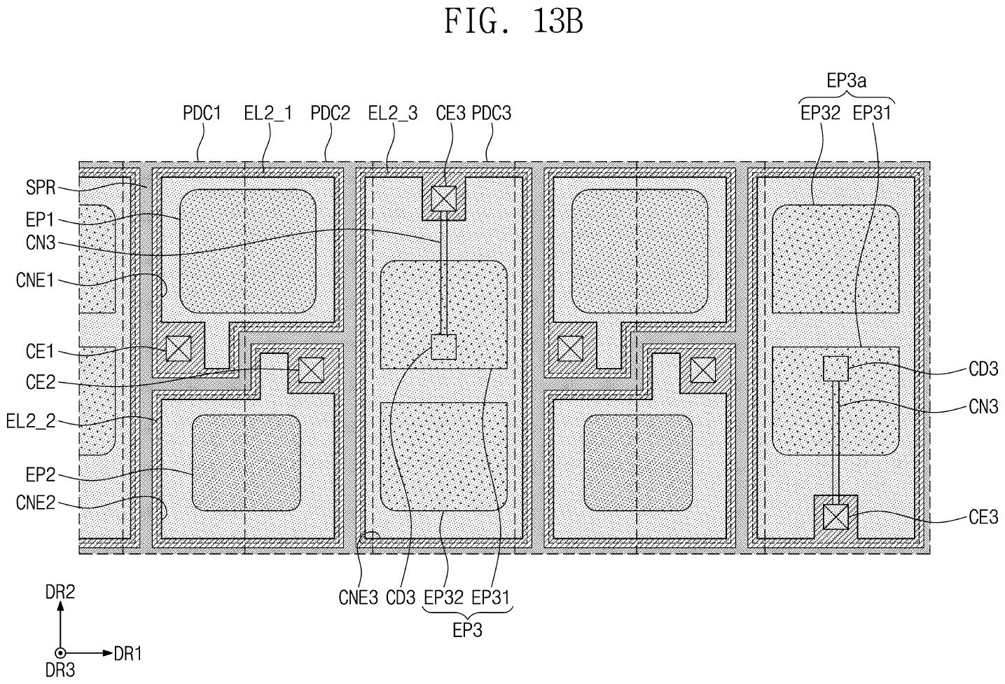

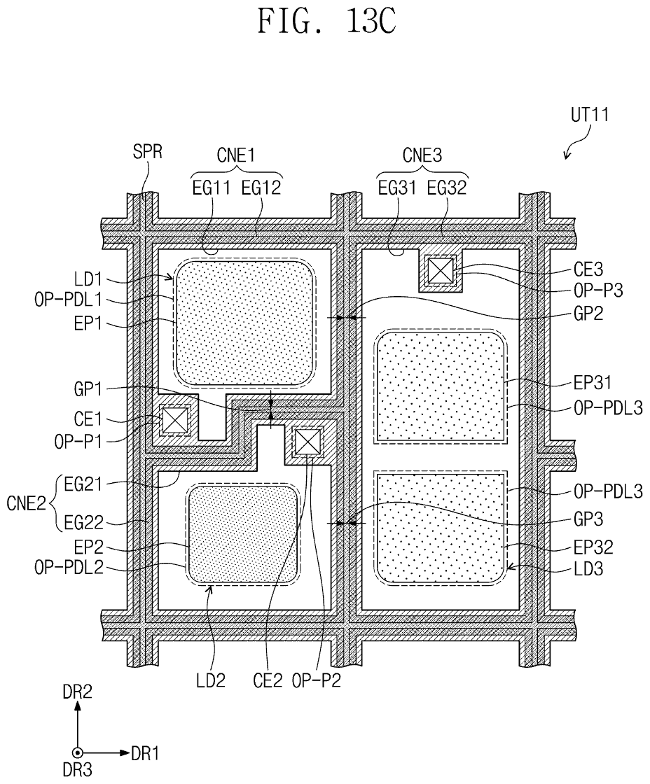

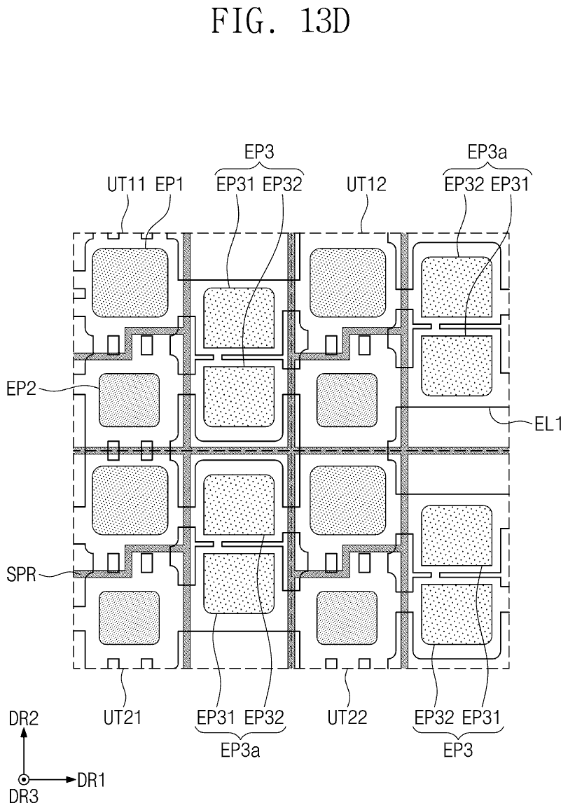

FIGS. 13A to 13D are enlarged plan views of partial areas of the display panel according to embodiments of the present disclosure.

Light emitting units UT11, UT12, UT21, and UT22 arranged in two rows and two columns are illustrated in FIG. 13A. Referring to FIG. 13A, light emitting parts in the first row Rk include light emitting parts that constitute the light emitting unit UT11 at the first row and the first column and the light emitting unit UT12 at the first row and the second column, and light emitting parts in the second row Rk+1 include light emitting parts that constitute the light emitting unit UT21 at the second row and the first column and the light emitting unit UT22 at the second row and the second column.

Each of light emitting parts EP1, EP2, and EP3 may correspond to the light emitting opening OP-PDL (refer to FIG. 14) that will be described below. That is, each of the light emitting parts EP1, EP2, and EP3 may be an area through which light is emitted by the above-described light emitting element. The light emitting parts EP1, EP2, and EP3 may correspond to components that form a unit for displaying an image on the display panel DP (refer to FIG. 1). More specifically, each of the light emitting parts EP1, EP2, and EP3 may correspond to an area defined by the light emitting opening OP-PDL that will be described below, particularly, an area defined by the lower surface of the light emitting opening OP-PDL.

The light emitting parts EP1, EP2, and EP3 may include the first light emitting part EP1, the second light emitting part EP2, and the third light emitting part EP3. The first light emitting part EP1, the second light emitting part EP2, and the third light emitting part EP3 may emit light of different colors. For example, the first light emitting part EP1 may emit red light, the second light emitting part EP2 may emit green light, and the third light emitting part EP3 may emit blue light. However, a combination of colors is not limited thereto. Alternatively, at least two of the first to third light emitting parts EP1, EP2, and EP3 may emit light of the same color. For example, the first to third light emitting parts EP1, EP2, and EP3 may all emit blue light or white light.

Among the first to third light emitting parts EP1, EP2, and EP3, the third light emitting part EP3 that displays light emitted by a third light emitting element may include two sub-light emitting parts EP31 and EP32 spaced apart from each other in the second direction DR2. Similar to the first light emitting part EP1 and the second light emitting part EP2, the third light emitting part EP3 may be implemented with one pattern having a one-body shape, and at least one of the first light emitting part EP1 and the second light emitting part EP2 may include sub-light emitting parts spaced apart from each other. However, the present disclosure is not limited to any one embodiment.

The light emitting parts in the first row Rk may include the first to third light emitting parts EP1, EP2, and EP3 constituting the light emitting unit UT11 at the first row and the first column and the first to third light emitting parts EP1, EP2, and EP3a constituting the light emitting unit UT12 at the first row and the second column, and the light emitting parts in the second row Rk+1 may include the first to third light emitting parts EP1, EP2, and EP3a constituting the light emitting unit UT21 at the second row and the first column and the first to third light emitting parts EP1, EP2, and EP3 constituting the light emitting unit UT22 at the second row and the second column.

In an embodiment of the present disclosure, the light emitting parts constituting the light emitting unit UT11 at the first row and the first column may have substantially the same shape as the light emitting parts constituting the light emitting unit UT22 at the second row and the second column. In addition, the light emitting parts constituting the light emitting unit UT12 at the first row and the second column may have substantially the same shape as the light emitting parts constituting the light emitting unit UT21 at the second row and the first column. The light emitting parts constituting the light emitting unit UT11 at the first row and the first column may have a shape different from the shape of the light emitting parts constituting the light emitting unit UT12 at the first row and the second column. For example, some of the light emitting parts in the first row Rk and some of the light emitting parts in the second row Rk+1 may have symmetrical shapes.

In an embodiment of the present disclosure, the shape and arrangement of the third light emitting part EP3a of the light emitting unit UT21 at the second row and the first column and the shape and arrangement of the third light emitting part EP3 of the light emitting unit UT11 at the first row and the first column have line symmetry with respect to an axis parallel to the first direction DR1, and the shape and arrangement of the third light emitting part EP3 of the light emitting unit UT22 at the second row and the second column and the shape and arrangement of the third light emitting part EP3a of the light emitting unit UT12 at the first row and the second column have line symmetry with respect to an axis parallel to the first direction DR1. In an embodiment, the third light emitting parts EP3 in diagonally adjacent pixels are arranged to exhibit line symmetry with respect to an axis parallel to the first direction DR1. For example, the light emitting parts at (row 2, column 1) and (row 1, column 1) are symmetrical, and so are those at (row 2, column 2) and (row 1, column 2). However, the present disclosure is not limited thereto.

In FIG. 13B, light emitting parts arranged in one row are illustrated. In FIG. 13B, for ease of description, a plurality of second electrodes EL2_1, EL2_2, and EL2_3, a plurality of pixel drivers PDC1, PDC2, and PDC3, first to third connecting electrodes CNE1, CNE2, and CNE3, and a separator SPR are illustrated. Among the components of the display panel, the separator SPR, the plurality of light emitting parts EP1, EP2, and EP3 disposed in areas partitioned by the separator SPR, and the plurality of connecting electrodes CNE1, CNE2, and CNE3 are illustrated in FIG. 13C. In an embodiment, the separator SPR is a structural element (e.g., an insulator) that spatially defines and separates the light emitting parts within a pixel or between adjacent pixels. It may serve as a bank or pixel defining layer formed between light emitting parts to prevent material mixing during deposition, guide the formation of the organic light emitting layers, and maintain uniform alignment of electrodes.

Referring to FIGS. 13B and 13C, the second electrodes EL2_1, EL2_2, and EL2_3 may be separated and electrically disconnected from one another by the separator SPR. In this embodiment, one light emitting unit UT11 may include three light emitting parts EP1, EP2, and EP3. Accordingly, the light emitting unit UT11 may include three second electrodes EL2_1, EL2_2, and EL2_3 (hereinafter, referred to as the first to third cathodes), three pixel drivers PDC1, PDC2, and PDC3, and three connecting lines CNE1, CNE2, and CNE3. However, the number and arrangement of light emitting parts included in the light emitting unit UT11 may be designed in various ways and are not limited to any one embodiment.

The first to third pixel drivers PDC1, PDC2, and PDC3 are electrically connected to first to third light emitting elements LD1, LD2, and LD3 including the first to third light emitting parts EP1, EP2, and EP3, respectively. The expression “connected” used herein includes not only physical direct contact but also electrical connection.

In addition, each of the areas where the first to third pixel drivers PDC1, PDC2, and PDC3 are defined on the plane as illustrated in FIG. 13B may correspond to a unit in which a transistor and capacitors that constitute a circuit PDC (refer to FIG. 14) for driving a light emitting element of a pixel are repeatedly arranged. According to the present disclosure, each of the first to third pixel drivers PDC1, PDC2, and PDC3 may have the structure of one of the pixel drive circuits PCij, PCaij, PCbij, PC-1ij, and PC-1aij described above with reference to FIGS. 2 to 11.

The first to third pixel drivers PDC1, PDC2, and PDC3 may be sequentially arranged in the first direction DR1. Meanwhile, the positions of the first to third pixel drivers PDC1, PDC2, and PDC3 may be independently designed, regardless of the positions or shapes of the first to third light emitting parts EP1, EP2, and EP3.

For example, the first to third pixel drivers PDC1, PDC2, and PDC3 may be disposed at positions different from the areas partitioned and defined by the separator SPR (that is, the positions at which the first to third cathodes EL2_1, EL2_2, and EL2_3 are disposed) or may be designed to have shapes and areas different from those of the first to third cathodes EL2_1, EL2_2, and EL2_3. Alternatively, the first to third pixel drivers PDC1, PDC2, and PDC3 may be disposed to overlap the positions at which the first to third light emitting parts EP1, EP2, and EP3 exist and may be designed in shapes similar to the shapes of the areas partitioned and defined by the separator SPR, for example, the first to third cathodes EL2_1, EL2_2, and EL2_3.

In this embodiment, the first to third pixel drivers PDC1, PDC2, and PDC3 are illustrated in a rectangular shape, the first to third light emitting parts EP1, EP2, and EP3 have smaller areas than the first to third pixel drivers PDC1, PDC2, and PDC3 and are arranged in a form different from that of the first to third pixel drivers PDC1, PDC2, and PDC3, and the first to third cathodes EL2_1, EL2_2, and EL2_3 are disposed at positions overlapping the first to third light emitting parts EP1, EP2 and EP3 and illustrated in an irregular shape.

Accordingly, as illustrated in FIG. 13B, the first pixel driver PDC1 may be disposed at a position that partially overlaps the first light emitting part EP1, the second light emitting part EP2, and another adjacent light emitting unit. The second pixel driver PDC2 may be disposed at a position that overlaps the first light emitting part EP1, the second light emitting part EP2, and the third cathode EL2_3. The third pixel driver PDC3 may be disposed at a position that overlaps the third light emitting part EP3. However, the positions of the first to third pixel drivers PDC1, PDC2, and PDC3 may be designed in various forms and arrangements independently of the first to third light emitting parts EP1, EP2, and EP3 and are not limited to any one embodiment.

The light emitting unit UT11 may include the first to third connecting electrodes CNE1, CNE2, and CNE3. The first connecting electrode CNE1 may electrically connect the first light emitting element LD1 that forms the first light emitting part EP1 (or, has the first light emitting part EP1 defined therein) and the first pixel driver PDC1. The second connecting electrode CNE2 may electrically connect the second light emitting element LD2 that forms the second light emitting part EP2 and the second pixel driver PDC2. The third connecting electrode CNE3 may electrically connect the third light emitting element LD3 that forms the third light emitting part EP3 and the third pixel driver PDC3.

Specifically, the first to third connecting electrodes CNE1, CNE2, and CNE3 may electrically connect the first to third cathodes EL2_1, EL2_2, and EL2_3 and the first to third pixel drivers PDC1, PDC2, and PDC3 in a one-to-one correspondence.

Each of the first to third connecting electrodes CNE1, CNE2, and CNE3 may be disposed on a pixel defining layer PDL (refer to FIG. 14) that will be described below. The first to third connecting electrodes CNE1, CNE2, and CNE3 may have ring shapes, rectangular frames or composite rectangular outlines that surround the corresponding first to third light emitting parts EP1, EP2, and EP3. In an embodiment of the present disclosure, each of the first to third connecting electrodes CNE1, CNE2, and CNE3 is illustrated as having a closed-line shape (e.g., a ring, rectangular frame, a polygon, or an irregular shape), but is not limited thereto. For example, at least some of the first to third connecting electrodes CNE1, CNE2, and CNE3 may have an open-loop shape in which a portion is cut off.

Since the first to third connecting electrodes CNE1, CNE2, and CNE3 have a loop shape, the degree of freedom in the positions where the first to third connecting electrodes CNE1, CNE2, and CNE3 and the first to third pixel drivers PDC1, PDC2, and PDC3 are connected may be enhanced. For example, the first connecting electrode CNE1 may be connected to the first pixel driver PDC1 through a first connection part CE1, the second connecting electrode CNE2 may be connected to the second pixel driver PDC2 through a second connection part CE2, and the third connecting electrode CNE3 may be connected to the third pixel driver PDC3 through a connecting line CN3. That is, connecting lines additionally connected to the first connecting electrode CNE1 and the second connecting electrode CNE2 may be omitted.

The connecting line CN3 may electrically connect the third pixel driver PDC3 and the third light emitting element LD3 constituting the third light emitting part EP3. Specifically, the connecting line CN3 may correspond to the node at which the light emitting element LD (refer to FIG. 2) is connected to the pixel driver (or, the pixel drive circuit PCij (refer to FIG. 2)).

The connecting line CN3 may include a third connection part CE3 and a drive connection part CD3. The third connection part CE3 may be provided on one side of the connecting line CN3, and the drive connection part CD3 may be provided on an opposite side of the connecting line CN3.

The drive connection part CD3 may be a part of the connecting line CN3 connected with the pixel driver PDC3. In this embodiment, the drive connection part CD3 may be connected with one electrode of a transistor constituting the pixel driver PDC3. Specifically, the drive connection part CD3 may be connected to the drain of the fifth transistor T5 illustrated in FIG. 2 or the drain of the fifth transistor T5-1 illustrated in FIG. 8. Accordingly, the position of the drive connection part CD3 may correspond to the position of the transistor of the pixel driver that is physically connected with the connecting line CN3. The third connection part CE3 may be a part of the connecting line CN3 connected with the third light emitting element LD. In this embodiment, the third connection part CE3 may be connected with the third connecting electrode CNE3.

The first connecting electrode CNE1 may include a first edge EG11 surrounding at least a portion of the first light emitting part EP1 and a second edge EG12 surrounding the first edge EG11. The second connecting electrode CNE2 may include a first edge EG21 surrounding at least a portion of the second light emitting part EP2 and a second edge EG22 surrounding the first edge EG21. The third connecting electrode CNE3 may include a first edge EG31 surrounding at least a portion of the third light emitting part EP3 and a second edge EG32 surrounding the first edge EG31.

The first to third connecting electrodes CNE1, CNE2, and CNE3 may be spaced apart from one another. For example, the gaps GP1, GP2, or GP3 between connecting electrodes adjacent to each other among the first to third connecting electrodes CNE1, CNE2, and CNE3 may overlap the separator SPR. For example, the first edges EG11, EG21, and EG31 of the first to third connecting electrodes CNE1, CNE2, and CNE3 should not be covered by the separator SPR, and the second edges EG12, EG22, and EG32 of the first to third connecting electrodes CNE1, CNE2, and CNE3 may overlap the separator SPR. Alternatively, the second edges EG12, EG22, and EG32 of the first to third connecting electrodes CNE1, CNE2, and CNE3 may be covered by the separator SPR.

In an embodiment of the present disclosure, the first to third connection parts CE1, CE2, and CE3 are disposed at positions not overlapping the first to third light emitting parts EP1, EP2, and EP3 when viewed from above the plane. For example, the light emitting opening OP-PDL (refer to FIG. 14) and through-holes OP-P (refer to FIG. 14) spaced apart from the light emitting opening OP-PDL may be defined in the pixel defining layer PDL.

The though-holes OP-P may include a first through-hole OP-P1, a second through-hole OP-P2, and a third through-hole OP-P3. The first to third connection parts CE1, CE2, and CE3 may be arranged to correspond to the first to third through-holes OP-P1, OP-P2, and OP-P3, respectively. The light emitting opening OP-PDL may include a first light emitting opening OP-PDL1, a second light emitting opening OP-PDL2, and a third light emitting opening OP-PDL3. The first to third light emitting parts EP1, EP2, and EP3 may be defined to correspond to the first to third light emitting openings OP-PDL1, OP-PDL2, and OP-PDL3, respectively. Accordingly, the first to third connection parts CE1, CE2, and CE3 may be disposed at positions spaced apart from the first to third light emitting parts EP1, EP2, and EP3.

The first to third connecting electrodes CNE1, CNE2, and CNE3 may be disposed on the pixel defining layer PDL (refer to FIG. 14). When viewed from above the plane, the first connecting electrode CNE1 may surround the first light emitting opening OP-PDL1, the second connecting electrode CNE2 may surround the second light emitting opening OP-PDL2, and the third connecting electrode CNE3 may surround the third light emitting opening OP-PDL3.

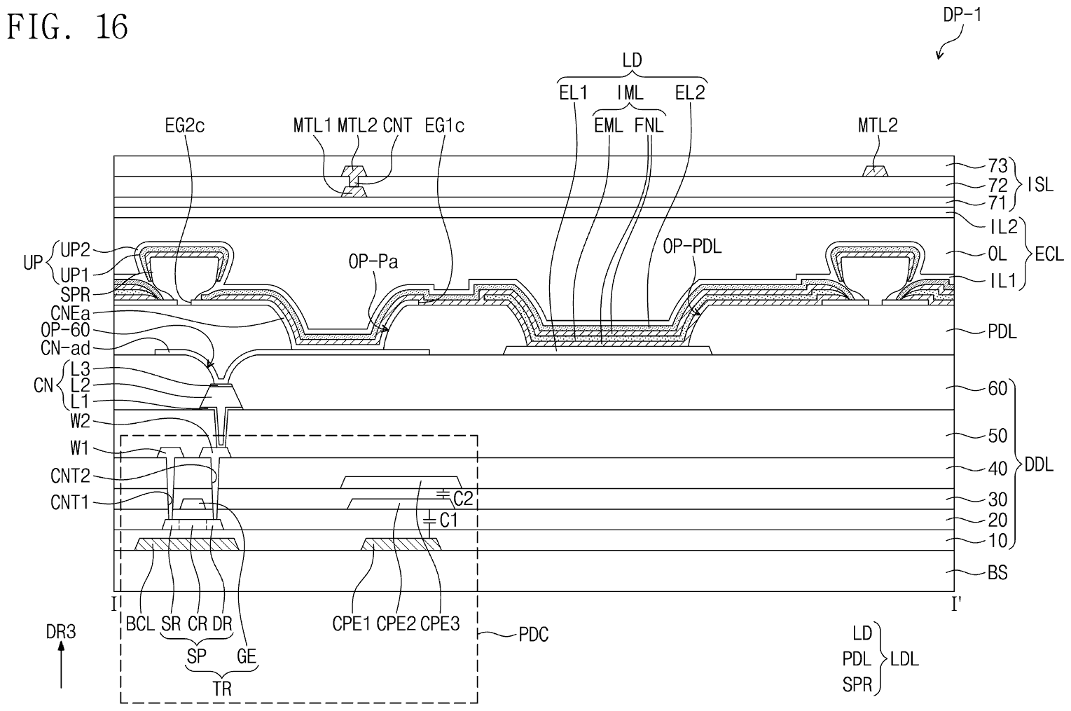

According to an embodiment of the present disclosure, the drive connection part CD3 where the connecting line CN3 is connected with a transistor TR (refer to FIG. 14) of the third pixel driver PDC3 may be defined at a position not overlapping the third connection part CE3 and disposed at a position overlapping the third light emitting part EP3 when viewed from above the plane. For example, the drive connection part CD3, where the connecting line CN3 is connected with a transistor TR (refer to FIG. 14) of the third pixel driver PDC3, may be defined at a position overlapping the third light emitting part EP3 and spaced apart from the third connection part CE3 when viewed from above the plane. For example, the connecting line CN3 may correspond to a connecting line CN-ad illustrated in FIG. 16, the drive connection part CD3 may correspond to a part making contact with an intermediate connecting electrode CN illustrated in FIG. 16, and the third connection part CE3 may correspond to a part making contact with a connecting electrode CNEa illustrated in FIG. 16. The third cathode EL2_3 and the pixel driver PDC3 may be connected through the connecting line CN3. Accordingly, in the design of the pixel driver PDC3, restrictions depending on the position or shape of the third light emitting part EP3 may be reduced, and thus the degree of freedom in design may be enhanced.

The first to third cathodes EL2_1, EL2_2, and EL2_3 may be connected with the first to third connecting electrodes CNE1, CNE2, and CNE3. For example, the lower surfaces of the first to third cathodes EL2_1, EL2_2, and EL2_3 may be connected with (or, brought into contact with) the upper surfaces of the first to third connecting electrodes CNE1, CNE2, and CNE3. Accordingly, the contact reliability (or, connection stability) of the first to third cathodes EL2_1, EL2_2, and EL2_3 and the first to third connecting electrodes CNE1, CNE2, and CNE3 may be further enhanced.

In addition, the connection areas where the first to third cathodes EL2_1, EL2_2, and EL2_3 and the first to third connecting electrodes CNE1, CNE2, and CNE3 are connected may surround at least portions of the first to third light emitting openings OP-PDL1, OP-PDL2, and OP-PDL3. The first to third cathodes EL2_1, EL2_2, and EL2_3 and the first to third connecting electrodes CNE1, CNE2, and CNE3 may be connected in areas adjacent to the separator SPR, and the contact areas may be defined to be adjacent to the separator SPR. That is, the first to third cathodes EL2_1, EL2_2, and EL2_3 and the first to third connecting electrodes CNE1, CNE2, and CNE3 need not be connected at specific points and may be connected over relatively wide areas, for example, areas similar to the shapes of the first to third connecting electrodes CNE1, CNE2, and CNE3. That is, the areas of connection contacts may be increased, and thus the connection may be stably performed.

In FIG. 13D, the separator SPR, the light emitting parts EP1, EP2, and EP3, and a first electrode EL1 are illustrated.

Referring to FIG. 13D, the first electrode EL1 (hereinafter, referred to as the anode) of a light emitting element LD (refer to FIG. 14) according to an embodiment of the present disclosure is commonly provided for the first to third light emitting parts EP1, EP2, and EP3. That is, the anode EL1 may be formed as one integrated layer in the entire display area DA. Accordingly, the layer of the anode EL1 may be disposed to overlap the separator SPR. Alternatively, the anodes EL1 of the light emitting elements LD may be formed as independent conductive patterns spaced apart from one another and may be electrically connected with one another through another conductive layer. Accordingly, the patterns of the anodes EL1 may be disposed so as not to overlap the separator SPR.

As described above, the first power ELVDD (refer to FIG. 1) may be applied to the anode EL1, and a common voltage may be provided to all of the light emitting parts. The anode EL1 may be connected with the first power line PL1 (refer to FIG. 2), which provides the first power ELVDD, in the peripheral area NDA or may be connected with the first power line PL1 (refer to FIG. 2) in the display area DA but is not limited to any one embodiment.

Meanwhile, a plurality of openings may be defined in the anode EL1 according to this embodiment. The openings may penetrate the layer of the anode EL1. The openings in the layer of the anode EL1 may be disposed at positions not overlapping the light emitting parts EP (refer to FIG. 12A) and may be defined at positions overlapping the separator SPR. For example, the openings in the layer of the anode EL1 may be defined at positions overlapping the separator SPR and spaced apart from the light emitting parts EP (refer to FIG. 12A). The openings may facilitate releasing gas generated from an organic layer disposed under the anode EL1, for example, a sixth insulating layer 60 (refer to FIG. 14) that will be described below. Accordingly, the gas of the organic layer disposed under the light emitting element may be sufficiently released in the process of manufacturing the display panel, and gas released from the organic layer after the manufacture of the display panel may be reduced. Thus, the speed at which the light emitting element becomes degraded may be decreased.

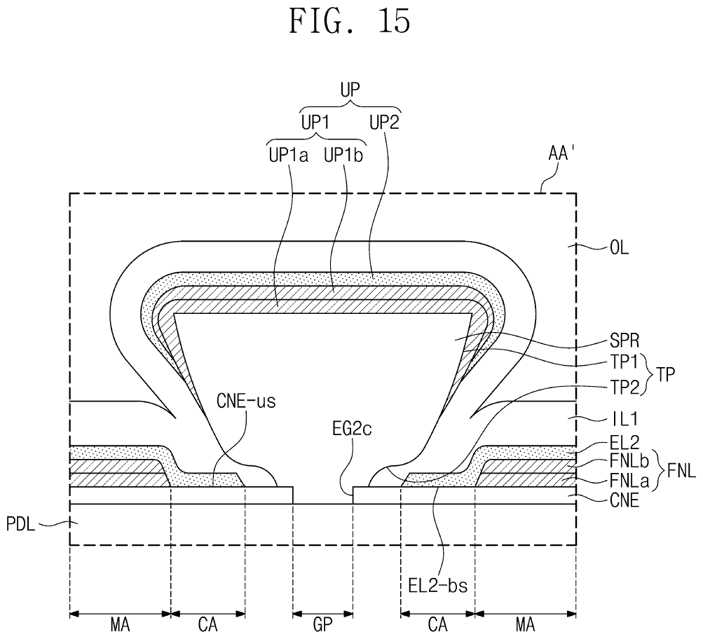

FIG. 14 is a sectional view of the display panel according to an embodiment of the present disclosure. FIG. 15 is an enlarged sectional view of a partial area of the display panel according to an embodiment of the present disclosure. FIG. 14 illustrates a sectional view illustrating a portion corresponding to line I-I′ of FIG. 13A. FIG. 15 illustrates an enlarged sectional view of area AA′ of FIG. 14.

Referring to FIGS. 14 and 15, the display panel DP according to an embodiment may include a base layer BS, a drive element layer DDL, a light emitting element layer LDL, an encapsulation layer ECL, and a sensing layer ISL. However, this is merely one example, and an embodiments of the present disclosure are not limited thereto. For example, the sensing layer ISL may be omitted from the display panel DP.

The drive element layer DDL may include a plurality of insulating layers 10, 20, 30, 40, 50, and 60 disposed on the base layer BS and a plurality of conductive patterns and semiconductor patterns disposed between the insulating layers 10, 20, 30, 40, 50, and 60. The conductive patterns and the semiconductor patterns may be disposed between the insulating layers 10, 20, 30, 40, 50, and 60 to constitute the pixel driver PDC. In FIG. 14, for ease of description, a cross-section of a partial region of an area in which one light emitting part is disposed is illustrated.

The base layer BS may be a member that provides a base surface on which the pixel driver PDC is disposed. The base layer BS may be a rigid substrate or may be a flexible substrate capable of being bent, folded, or rolled. The base layer BS may be a glass substrate, a metal substrate, or a polymer substrate. However, embodiments of the present disclosure are not limited thereto. For example, the base layer BS may be an inorganic layer, an organic layer, or a composite layer.

The base layer BS may have a multi-layer structure. The base layer BS may include a first polymer resin layer, a silicon oxide (SiOx) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layers may include a polyimide-based resin. Alternatively, the polymer resin layers may include at least one of an acrylic resin, a methacrylic resin, a polyisoprene resin, a vinyl resin, an epoxy resin, a urethane-based resin, a celluosic resin, a siloxane-based resin, a polyamide resin, and a perylene-based resin. Meanwhile, a “˜˜”-based resin used herein means a resin containing a “˜˜” functional group.

Insulating layers, conductive layers, and semiconductor layers disposed on the base layer BS may be formed through a process such as coating or deposition. Thereafter, the insulating layers, the semiconductor layers, and the conductive layers may be selectively subjected to patterning by performing a photolithography process a plurality of times. Accordingly, holes may be formed in the insulating layers, or a semiconductor pattern, a conductive pattern, and a signal line may be formed on the insulating layers.

The drive element layer DDL may include the first to sixth insulating layers 10, 20, 30, 40, 50, and 60 sequentially stacked on the base layer BS and the pixel driver PDC. One transistor TR and two capacitors C1 and C2 of the pixel driver PDC are illustrated in FIG. 14.

The transistor TR may correspond to a transistor connected to the light emitting element LD through an intermediate connecting electrode CN and a connecting electrode CNE, that is, a connection transistor connected to a node (e.g., the first node N1 (refer to FIG. 2)) corresponding to the cathode of the light emitting element LD. Specifically, the transistor TR may correspond to the fifth transistor T5 of FIGS. 2, 4, and 6 or the fifth transistor T5-1 of FIGS. 8 and 10. Other transistors constituting the pixel driver PDC may have the same structure as the transistor TR (hereinafter, referred to as the connection transistor) illustrated in FIG. 14. However, the embodiments are not limited thereto. For example, the other transistors constituting the pixel driver PDC may have a structure different from that of the connection transistor TR but are not limited to any one embodiment.

The first insulating layer 10 may be disposed on the base layer BS. The first insulating layer 10 may be an inorganic layer and/or an organic layer and may have a single-layer structure or a multi-layer structure. The first insulating layer 10 may include at least one of aluminum oxide, titanium oxide, silicon oxide, silicon nitride, silicon oxy nitride, zirconium oxide, and hafnium oxide. In an embodiment, the first insulating layer 10 is a single silicon oxide layer. Meanwhile, insulating layers to be described below may be inorganic layers and/or organic layers and may have a single-layer structure or a multi-layer structure. The inorganic layers may include at least one of the aforementioned materials, but are not limited thereto.

Meanwhile, the first insulating layer 10 may cover a lower conductive layer BCL. That is, the display panel DP may further include the lower conductive layer BCL disposed to overlap the connection transistor TR. The lower conductive layer BCL may block an influence of an electrical potential due to a polarization phenomenon of the base layer BS on the connection transistor TR. In addition, the lower conductive layer BCL may block light incident to the connection transistor TR from below. At least one of an inorganic barrier layer and a buffer layer may be additionally disposed between the lower conductive layer BCL and the base layer BS.

The lower conductive layer BCL may include a reflective metal. For example, the lower conductive layer BCL may include titanium (TI), molybdenum (Mo), an alloy containing molybdenum, aluminum (Al), an alloy containing aluminum, aluminum nitride (AlN), tungsten (W), tungsten nitride (WN), and copper (Cu).

In an embodiment, the lower conductive layer BCL is connected with the source of the connection transistor TR (or, the transistor) through a source electrode pattern W1. In this case, the lower conductive layer BCL may be synchronized with the source of the transistor TR. However, the embodiments are not limited thereto. For example, the lower conductive layer BCL may be connected to the gate of the transistor TR and may be synchronized with the gate. Alternatively, the lower conductive layer BCL may be connected to another electrode and may independently receive a constant voltage or a pulse signal. In another embodiment, the lower conductive layer BCL may be provided in a form isolated from another conductive pattern. The lower conductive layer BCL according to an embodiment of the present disclosure may be provided in various forms and is not limited to any one embodiment.

The connection transistor TR may be disposed on the first insulating layer 10. The connection transistor TR may include a semiconductor pattern SP and a gate electrode GE. The semiconductor pattern SP may be disposed on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO), or indium oxide (In₂O₃). The semiconductor pattern SP may include amorphous silicon, low-temperature polycrystalline silicon, or polycrystalline silicon, but is not limited thereto.

The semiconductor pattern SP may include a source area SR, a drain area DR, and a channel area CR distinguished from one another depending on the degree of conductivity. The channel area CR may be a portion overlapping the gate electrode GE when viewed from above the plane. The source area SR and the drain area DR may be portions spaced apart from each other with the channel area CR therebetween. When the semiconductor pattern SP is an oxide semiconductor, the source area SR and the drain area DR may be reduced areas. Accordingly, the source area SR and the drain area DR may have a higher reduced-metal content than the channel area CR. Alternatively, when the semiconductor pattern SP is polycrystalline silicon, the source area SR and the drain area DR may be highly doped areas.

The source area SR and the drain area DR may have a higher conductivity than the channel area CR. The source area SR may correspond to the source electrode of the connection transistor TR, and the drain area DR may correspond to the drain electrode of the connection transistor TR. As illustrated in FIG. 5, the source electrode pattern W1 and a drain electrode pattern W2 connected to the source area SR and the drain area DR, respectively, may be further included. Specifically, each of the source electrode pattern W1 and the drain electrode pattern W2 may be integrally formed with one of several lines constituting the pixel driver (or, the pixel drive circuit) but is not limited to any one embodiment.

The second insulating layer 20 may commonly overlap a plurality of pixels and may cover the semiconductor pattern SP. The second insulating layer 20 may be an inorganic layer and/or an organic layer and may have a single-layer structure or a multi-layer structure. The second insulating layer 20 may include at least one of aluminum oxide, titanium oxide, silicon oxide, silicon nitride, silicon oxy nitride, zirconium oxide, and hafnium oxide. In an embodiment, the second insulating layer 20 is a single silicon oxide layer.

The gate electrode GE may be disposed on the second insulating layer 20. The gate electrode GE may correspond to the gate of the connection transistor TR. In addition, the gate electrode GE may be disposed over the semiconductor pattern SP. However, the embodiments are not limited thereto. For example, the gate electrode GE may be disposed under the semiconductor pattern SP but is not limited to any one embodiment.

The gate electrode GE may include titanium (TI), silver (Ag), molybdenum (Mo), aluminum (Al), aluminum nitride (AlN), tungsten (W), tungsten nitride (WN), copper (Cu), or an alloy thereof, but is not limited thereto.

The third insulating layer 30 may be disposed on the gate electrode GE. The third insulating layer 30 may be an inorganic layer and/or an organic layer and may have a single-layer structure or a multi-layer structure. The third insulating layer 30 may include at least one of aluminum oxide, titanium oxide, silicon oxide, silicon nitride, silicon oxy nitride, zirconium oxide, and hafnium oxide.

Among a plurality of conductive patterns W1, W2, CPE1, CPE2, and CPE3, the first capacitor electrode CPE1 and the second capacitor electrode CPE2 constitute the first capacitor C1. The first capacitor electrode CPE1 and the second capacitor electrode CPE2 may be spaced apart from each other with the first insulating layer 10 and the second insulating layer 20 therebetween.

In an embodiment of the present disclosure, the first capacitor electrode CPE1 and the lower conductive layer BCL have a one-body shape. For example, CPE1 and BCL may be formed as a single, continuous physical structure, rather than being separate layers or components. In addition, the second capacitor electrode CPE2 and the gate electrode GE may have a one-body shape. For example, CPE2 and GE may be formed as a single, continuous physical structure, rather than being separate layers or components.

The third capacitor electrode CPE3 may be disposed on the third insulating layer 30. The third capacitor electrode CPE3 may be spaced apart from the second capacitor electrode CPE2 with the third insulating layer 30 therebetween and may overlap the second capacitor electrode CPE2 when viewed from above the plane. The third capacitor electrode CPE3, together with the second capacitor electrode CPE2, may constitute the second capacitor C2.

The fourth insulating layer 40 may be disposed on the third insulating layer 30 and/or the third capacitor electrode CPE3. The fourth insulating layer 40 may be an inorganic layer and/or an organic layer and may have a single-layer structure or a multi-layer structure. The fourth insulating layer 40 may include at least one of aluminum oxide, titanium oxide, silicon oxide, silicon nitride, silicon oxy nitride, zirconium oxide, and hafnium oxide.

The source electrode pattern W1 and the drain electrode pattern W2 may be disposed on the fourth insulating layer 40. The source electrode pattern W1 may be connected to the source area SR of the connection transistor TR through a first contact hole CNT1, and the source electrode pattern W1 and the source area SR of the semiconductor pattern SP may function as the source of the transistor TR. The drain electrode pattern W2 may be connected to the drain area DR of the connection transistor TR through a second contact hole CNT2, and the drain electrode pattern W2 and the drain area DR of the semiconductor pattern SP may function as the drain of the connection transistor TR. The fifth insulating layer 50 may be disposed on the source electrode pattern W1 and the drain electrode pattern W2.

The intermediate connecting electrode CN may be disposed on the fifth insulating layer 50. The intermediate connecting electrode CN may electrically connect the pixel driver PDC and the light emitting element LD. That is, the intermediate connecting electrode CN may electrically connect the connection transistor TR and the light emitting element. The intermediate connecting electrode CN may be a connection node that connects the pixel driver PDC and the light emitting element LD. That is, the intermediate connecting electrode CN may correspond to the first node N1 (refer to FIG. 2).

The sixth insulating layer 60 may be disposed on the intermediate connecting electrode CN. The sixth insulating layer 60 may be disposed on the fifth insulating layer 50 and may cover at least a portion of the intermediate connecting electrode CN. Each of the fifth insulating layer 50 and the sixth insulating layer 60 may be an organic layer. For example, each of the fifth insulating layer 50 and the sixth insulating layer 60 may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vynyl alcohol-based polymer, or a blend thereof.

A through-hole OP-60 may be formed in the sixth insulating layer 60 to expose at least a portion of the intermediate connecting electrode CN. The intermediate connecting electrode CN may be connected to the connecting electrode CNE through a portion exposed from the sixth insulating layer 60 and may be electrically connected with the light emitting element LD. That is, the intermediate connecting electrode CN, together with the connecting electrode CNE, may electrically connect the connection transistor TR and the light emitting element LD. The area where the intermediate connecting electrode CN and the connecting electrode CNE are connected may be referred to as a connection area CNA. The connection area CNA may be defined by the through-hole OP-60. According to an embodiment of the present disclosure, the sixth insulating layer 60 is omitted from the display panel DP, or a plurality of sixth insulating layers 60 may be provided in the display panel DP. However, the present disclosure is not limited thereto. When the sixth insulating layer 60 is omitted, the intermediate connecting electrode CN may also be omitted.

The intermediate connecting electrode CN may include a first layer L1, a second layer L2, and a third layer L3 sequentially stacked in the third direction DR3. The second layer L2 may include a material different from that of the first layer L1. In addition, the second layer L2 may include a material different from that of the third layer L3. In an embodiment, the second layer L2 has a greater thickness than the first layer L1. In addition, the second layer L2 may have a greater thickness than the third layer L3. The second layer L2 may include a highly conductive material. In an embodiment, the second layer L2 may include aluminum (Al).

The light emitting element layer LDL may be disposed on the drive element layer DDL. The light emitting element layer LDL may include the pixel defining layer PDL, the light emitting element LD, and the separator SPR.

The pixel defining layer PDL may be an organic layer. For example, the pixel defining layer PDL may include a general purpose polymer, such as benzocyclobutene (BCB), polyimide, hexamethyldisiloxane (HMDSO), Polymethylmethacrylate (PMMA), or Polystyrene (PS), a polymer derivative having a phenolic group, an acrylic polymer, an imide-based polymer, an aryl ether-based polymer, an amide-based polymer, a fluorine-based polymer, a p-xylene-based polymer, a vynyl alcohol-based polymer, or a blend thereof.

In an embodiment, the pixel defining layer PDL has a property of absorbing light. For example, the pixel defining layer PDL may be black in color. That is, the pixel defining layer PDL may include a black coloring agent. The black coloring agent may include a black dye or a black pigment. The black coloring agent may include carbon black, metal such as chromium, or oxide thereof. The pixel defining layer PDL may correspond to a light blocking pattern having light-blocking characteristics.

The opening OP-PDL (hereinafter, referred to as the light emitting opening) that exposes at least a portion of the first electrode EL1 that will be described below may be defined in the pixel defining layer PDL. A plurality of light emitting openings OP-PDL may be provided. The plurality of light emitting openings OP-PDL may be disposed to correspond to light emitting elements, respectively. All components of the light emitting element LD may be disposed in the light emitting opening OP-PDL to overlap one another, and the light emitting opening OP-PDL may be an area where light emitted by the light emitting element LD is substantially displayed. Accordingly, the shape of the first light emitting part EP1 (refer to FIG. 13A) may substantially correspond to the shape of the light emitting opening OP-PDL when viewed from above the plane. The area corresponding to the first light emitting part EP1, that is, the area defined by the light emitting opening OP-PDL may be referred to as an emissive area EA.

The connecting electrode CNE may be disposed on the pixel defining layer PDL. The connecting electrode CNE may electrically connect the pixel driver PDC and the light emitting element LD. That is, the pixel driver PXC may be electrically connected to the light emitting element LD through the intermediate connecting electrode CN and the connecting electrode CNE. The connecting electrode CNE may correspond to the first connecting electrode CNE1 illustrated in FIG. 13A. The second connecting electrode CNE2 (refer to FIG. 13A) and the third connecting electrode CNE3 (refer to FIG. 13A) may also have a structure similar to that of the connecting electrode CNE.

The connecting electrode CNE may include a first edge EG1c adjacent to the light emitting opening OP-PDL and a second edge EG2c surrounding the first edge EG1c. A second electrode EL2 of the light emitting element LD may be brought into contact with the connecting electrode CNE in an area adjacent to the second edge EG2c.

The connecting electrode CNE may include transparent conductive oxide (TCO) such as indium tin oxide (ITO), indium zinc oxide (IZO), indium gallium zinc oxide (IGZO), zinc oxide (ZnOx), or indium oxide (In₂O₃). However, the material of the connecting electrode CNE is not limited to the aforementioned examples. For example, the connecting electrode CNE may include a metallic material.

The through-hole OP-P spaced apart from the light emitting opening OP-PDL may be defined in the pixel defining layer PDL. A plurality of through-holes OP-P may be provided. The plurality of through-holes OP-P may be disposed to correspond to the light emitting elements, respectively. In an embodiment, a size of the through-hole OP-P defined in the pixel defining layer PDL is greater than a size of the through-hole OP-60 defined in the sixth insulating layer 60. The connecting electrode CNE may be disposed in the through-hole OP-P and the through-hole OP-60 and may be connected with the intermediate connecting electrode CN.

The light emitting element LD may include the first electrode EL1, an intermediate layer IML, and the second electrode EL2.

The first electrode EL1 may be a transflective electrode, a transmissive electrode, or a reflective electrode. According to an embodiment of the present disclosure, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof and a transparent or translucent electrode layer formed on the reflective layer. The transparent or translucent electrode layer may include at least one of indium tin oxide (ITO), indium zinc oxide (IZO), indium gallium zinc oxide (IGZO), zinc oxide (ZnO), or indium oxide (In₂O₃) and aluminum-doped zinc oxide (AZO). For example, the first electrode EL1 may include a stacked structure of ITO/Ag/ITO.

In an embodiment, the first electrode EL1 is the anode of the light emitting element LD. That is, the first electrode EL1 may be connected with the first power line PL1 (refer to FIG. 2), and the first power ELVDD (refer to FIG. 2) may be applied to the first electrode EL1. The first electrode EL1 may be connected with the first power line PL1 in the display area DA (refer to FIG. 12A or 12B) or may be connected with the first power line PL1 in the peripheral area NDA. In the latter case, the first power line PL1 may be disposed in the peripheral area NDA (refer to FIG. 12A or 12B), and the first electrode EL1 may have a shape extending to the peripheral area NDA.

In the sectional view of FIG. 14, the first electrode EL1 is illustrated as overlapping the light emitting opening OP-PDL and not overlapping the separator SPR. However, as described above with reference to FIG. 13D, the first electrodes EL1 of the light emitting elements may have a one-body shape and may have a mesh or grid shape in which openings are defined in a partial area. That is, as long as the same first power supply voltage VDD is capable of being applied to the first electrode EL1 of each of the plurality of light emitting elements, the shape of the first electrode EL1 may be provided in various ways and is not limited to any one embodiment. In other words, the first electrode EL1 may take various shapes, as long as the same first power supply voltage VDD can be applied to the first electrode EL1 of each of the plurality of light emitting elements.

The intermediate layer IML may be disposed between the first electrode EL1 and the second electrode EL2. The intermediate layer IML may include an emissive layer EML and a functional layer FNL. The light emitting element LD may include the intermediate layer IML having various structures and is not limited to any one embodiment. For example, the functional layer FNL may include a plurality of layers or may include two or more layers spaced apart from each other with the emissive layer EML therebetween.

Referring to FIGS. 14 and 15, the functional layer FNL may be disposed between the first electrode EL1 and the second electrode EL2. The functional layer FNL may include a first intermediate functional layer FNLa disposed between the first electrode EL1 and the emissive layer EML and a second intermediate functional layer FNLb disposed between the second electrode EL2 and the emissive layer EML. In this embodiment, the emissive layer EML is illustrated as being included in the functional layer FNL. That is, it may be understood that the emissive layer EML is disposed between the first intermediate functional layer FNLa and the second intermediate functional layer FNLb.

The functional layer FNL may control the movement of charges between the first electrode EL1 and the second electrode EL2. For example, the first intermediate functional layer FNLa may include a hole injection/transport material and/or an electron injection/transport material. The second intermediate functional layer FNLb may include at least one of an electron blocking layer, a hole transport layer, a hole injection layer, a hole blocking layer, an electron transport layer, an electron injection layer, and a charge generation layer.

The emissive layer EML may include an organic luminescent material. Alternatively, the emissive layer EML may include an inorganic luminescent material or may be provided as a mixed layer of an organic luminescent material and an inorganic luminescent material. In this embodiment, the emissive layers EML included in the adjacent light emitting parts EP (refer to FIG. 12A) may include luminescent materials that display different colors. For example, the emissive layer EML included in each of the light emitting parts EP may provide one of red light, green light, and blue light. However, without being limited thereto, the emissive layers EML disposed in all of the light emitting parts EP may include a luminescent material that displays the same color. In this case, the emissive layer EML may provide blue light or white light.

The second electrode EL2 may be disposed on the intermediate layer IML. As described above, the second electrode EL2 may be connected to the connecting electrode CNE and may be electrically connected to the pixel driver PDC. That is, the second electrode EL2 may be electrically connected with the connection transistor TR through the connecting electrode CNE.

The separator SPR may be disposed on the pixel defining layer PDL. In addition, the separator SPR may be disposed over the gap GP between the connecting electrode CNE disposed on the pixel defining layer PDL and an adjacent connecting electrode adjacent to the connecting electrode CNE.

In an embodiment, the second electrode EL2 and the functional layer FNL may be commonly formed for the plurality of pixels by deposition through an open mask. In this case, the second electrode EL2 and the functional layer FNL may be divided from each other by the separator SPR. For example, the separator SPR may separate the second electrode EL2 from the functional layer FNL. As described above, the separator SPR may have a closed-line shape for each of the light emitting parts, and thus the second electrode EL2 and the functional layer FNL may have a split shape for each light emitting part. That is, the second electrode EL2 and the intermediate layer IML may be electrically independent for each of adjacent pixels. For example, the second electrode EL2 and the functional layer FNL may be divided into separate regions corresponding to each light emitting part, such that they are not formed as a continuous layer across multiple light emitting parts.

In an embodiment, the separator SPR has an inverted tapered shape. That is, the separator SPR may have a shape in which the width is increased farther away from the upper surface of the pixel defining layer PDL. For example, the separator SPR may be shaped such that its width becomes greater as it extends away from the upper surface of the pixel defining layer PDL. A side surface TP of the separator SPR may have a shape in which a taper angle inclined with respect to the upper surface of the pixel defining layer PDL is an obtuse angle. However, the embodiments are not limited thereto. As long as the separator SPR is capable of electrically disconnecting the second electrode EL2 for each pixel, the taper angle of the separator SPR may be set in various ways. For example, the separator SPR may have a dual structure with different taper angles. In addition, the separator SPR may have a structure such as a tip portion (e.g., a tapered or pointed end) but is not limited to any one embodiment.

As illustrated in FIGS. 14 and 15, the separator SPR may have a dual inverted tapered shape. The side surface TP of the separator SPR may include a first side surface TP1 and a second side surface TP2 that have different taper angles. The taper angle formed by the first side surface TP1 of the separator SPR with respect to the upper surface of the pixel defining layer PDL may be different from the taper angle formed by the second side surface TP2 of the separator SPR with respect to the upper surface of the pixel defining layer PDL. The taper angles may be obtuse angles. For example, as illustrated in FIG. 15, the taper angle formed by the first side surface TP1 with respect to the upper surface of the pixel defining layer PDL may be smaller than the taper angle formed by the second side surface TP2 with respect to the upper surface of the pixel defining layer PDL. However, the embodiments are not limited thereto. For example, the taper angles may be set in various ways as long as the separator SPR is capable of electrically disconnecting the second electrode EL2 for each pixel. In addition, the separator SPR may have a structure such as a tip portion but is not limited to any one embodiment.

The separator SPR may include an insulating material. In particular, the separator SPR may include an organic insulating material. Alternatively, the separator SPR may include an inorganic insulating material. In another case, the separator SPR may be constituted by multiple layers of an organic insulating material and an inorganic insulating material. In some embodiments, the separator SPR may include a conductive material. That is, the type of material of the separator SPR is not particularly limited as long as the separator SPR is capable of electrically disconnecting the second electrode EL2 for each pixel.

A dummy layer UP may be disposed on the separator SPR. The dummy layer UP may include a first dummy layer UP1 disposed on the separator SPR and a second dummy layer UP2 disposed on the first dummy layer UP1. The first dummy layer UP1 may be formed through the same process as the intermediate layer IML and may include the same material as the intermediate layer IML. The first dummy layer UP1 may include a first-first dummy layer UP1a and a first-second dummy layer UP1b. The first-first dummy layer UP1a may be formed through the same process as the first intermediate functional layer FNLa and may include the same material as the first intermediate functional layer FNLa. The first-second dummy layer UP1b may be formed through the same process as the second intermediate functional layer FNLb and may include the same material as the second intermediate functional layer FNLb. The second dummy layer UP2 may be formed through the same process as the second electrode EL2 and may include the same material as the second electrode EL2. That is, the first dummy layer UP1 and the second dummy layer UP2 may be simultaneously formed in the process of forming the functional layer FNL and the second electrode EL2. As illustrated in FIG. 15, the dummy layer UP may be formed not only on the upper surface of the separator SPR but also on a portion of the side surface TP of the separator SPR. In an embodiment, the dummy layer UP is omitted from the display panel DP. The dummy layer UP should not make contact with the connecting electrode CNE and the second electrode EL2. The second dummy layer UP2 included in the dummy layer UP should not make contact with the connecting electrode CNE and the second electrode EL2.

The second electrode EL2 is brought into contact with the connecting electrode CNE through a contact area CA. The contact area CA is adjacent to the separator SPR. In the contact area CA, the upper surface CNE-us of the connecting electrode CNE is brought into contact with the lower surface EL2-bs of the second electrode EL2. Meanwhile, since the separator SPR has an inverted tapered shape and the contact area CA is adjacent to the separator SPR, at least a portion of the contact area CA where the second electrode EL2 and the connecting electrode CNE are brought into contact with each other may be disposed under the side surface TP of the separator SPR.

In an embodiment, at least a portion of the connecting electrode CNE may be disposed under the separator SPR. The separator SPR may be disposed over the gap GP between the connecting electrode CNE and the adjacent connecting electrode adjacent to the connecting electrode CNE, and the second edge EG2c of the second electrode EL2 may be covered by the separator SPR.

The display panel DP according to an embodiment may include an intermediate area MA disposed between the emissive area EA in which the light emitting element LD is disposed and the contact area CA. The intermediate area MA may be an area in which at least a portion of the intermediate layer IML is disposed. In the intermediate area MA, the functional layer FNL included in the intermediate layer IML may be disposed between the connecting electrode CNE and the second electrode EL2. That is, in the intermediate area MA, the connecting electrode CNE and the second electrode EL2 may be spaced apart from each other with the functional layer FNL therebetween.

The intermediate area MA may be adjacent to the contact area CA. The functional layer FNL disposed in the intermediate area MA may include the first intermediate functional layer FNLa and the second intermediate functional layer FNLb described above. The first intermediate functional layer FNLa may be disposed between the first electrode EL1 and the emissive layer EML in the emissive area EA, and the second intermediate functional layer FNLb may be disposed between the second electrode EL2 and the emissive layer EML in the emissive area EA.

In the display panel DP according to an embodiment, the functional layer FNL and the second electrode EL2 may be formed through different deposition processes. The second electrode EL2 may be formed by a deposition method that deposits a deposition material at a low incidence angle when compared to a deposition method that forms the functional layer FNL. For example, the functional layer FNL may be formed through thermal evaporation, while the second electrode EL2 may be covered using a sputtering method. During the formation of the functional layer FNL, the deposition material may not reach the side surface TP of the separator SPR. Therefore a portion of the connecting electrode CNE may remain exposed. The second electrode EL2 may be formed closer to the separator SPR than the functional layer FNL and may make contact with the upper surface CNE-us of the connecting electrode CNE on which the second electrode EL2 is exposed. That is, the contact area CA where the second electrode EL2 and the connecting electrode CNE come into contact, may be formed as a result of the difference between the deposition methods used for forming the functional layer FNL and the second electrode EL2.

Meanwhile, as illustrated in FIG. 14, the connection area CNA where the connecting electrode CNE is connected to the intermediate connecting electrode CN may be disposed between the emissive area EA and the contact area CA. The connection area CNA may overlap the intermediate area MA. At least a portion of the intermediate layer IML may be disposed to overlap the connection area CNA. In the display panel DP of an embodiment, the functional layer FNL included in the intermediate layer IML may be disposed to overlap the connection area CNA.

According to an embodiment of the present disclosure, the connecting electrode CNE has a shape surrounding at least a portion of the emissive area EA where the light emitting element LD is disposed. Accordingly, the degree of freedom in the position where the connecting electrode CNE and the light emitting element LD are connected and the degree of freedom in the position where the connecting electrode CNE and the pixel driver PDC are connected may be enhanced. In addition, the upper surface CNE-us of the connecting electrode CNE may be brought into contact with the lower surface EL2-bs of the second electrode EL2 of the light emitting element LD through the contact area CA defined adjacent to the separator SPR. Accordingly, the contact reliability of the connecting electrode CNE and the second electrode EL2 may be enhanced. Since the lower surface of the connecting electrode CNE and the upper surface of the intermediate connecting electrode CN are brought into contact with each other, the contact reliability may be enhanced. In the display panel DP according to an embodiment, the sizes of the through-holes OP-P and OP-60 for connecting the connecting electrode CNE and the intermediate connecting electrode CN may be decreased or minimized through the above-described structure, and thus the area or resolution of the light emitting part of the display panel DP may be easily increased.

Referring back to FIG. 14, the encapsulation layer ECL may be disposed on the light emitting element layer LDL. The encapsulation layer ECL may cover the light emitting element LD and may cover the separator SPR. The encapsulation layer ECL may include a first inorganic layer IL1, an organic layer OL, and a second inorganic layer IL2 sequentially stacked one above another. The encapsulation layer ECL may further include a plurality of inorganic layers and a plurality of organic layers, but is not limited thereto. In addition, the encapsulation layer ECL may be a glass substrate.

The first inorganic layer IL1 and the second inorganic layer IL2 may protect the light emitting element LD from moisture and oxygen outside the display panel DP, and the organic layer OL may protect the light emitting element LD from foreign matter, such as particles that remain during the formation of the first inorganic layer IL1. The first inorganic layer IL1 and the second inorganic layer IL2 may include a silicon nitride layer, a silicon oxy nitride layer, a silicon oxide layer, a titanium oxide layer, or an aluminum oxide layer. The organic layer OL may include an acrylic organic layer, but is not limited thereto.

The sensing layer ISL may sense an external input. In an embodiment, the sensing layer ISL is formed on the encapsulation layer ECL through a continuous process. The sensing layer ISL may be directly disposed on the encapsulation layer ECL. The expression “directly disposed” used herein may mean that another component is not disposed between the sensing layer ISL and the encapsulation layer ECL. That is, a separate adhesive member may not be disposed between the sensing layer ISL and the encapsulation layer ECL. However, the embodiments are not limited thereto. For example, in a display panel DP according to an embodiment of the present disclosure, the sensing layer ISL may be separately formed and then coupled with the display panel DP through an adhesive member but is not limited to any one embodiment.

The sensing layer ISL may include a plurality of conductive layers and a plurality of insulating layers. The plurality of conductive layers may include a first sensing conductive layer MTL1 and a second sensing conductive layer MTL2, and the plurality of insulating layers may include a first sensing insulation layer 71, a second sensing insulation layer 72, and a third sensing insulation layer 73. However, the embodiments are not limited thereto. For example, the number of conductive layers and the number of insulating layers are not limited to any one embodiment.

Each of the first to third sensing insulation layers 71, 72, and 73 may have a single-layer structure or may have a multi-layer structure stacked in the third direction DR3. The first to third sensing insulation layers 71, 72, and 73 may include an inorganic film. The inorganic film may include at least one of aluminum oxide, titanium oxide, silicon oxide, silicon nitride, silicon oxy nitride, zirconium oxide, and hafnium oxide. The first to third sensing insulation layers 71, 72, and 73 may include an organic film. The organic film may include at least one of an acrylic resin, a methacrylic resin, a polyisoprene resin, a vinyl resin, an epoxy resin, a urethane-based resin, a celluosic resin, a siloxane-based resin, a polyimide resin, a polyamide resin, and a perylene-based resin.

The first sensing conductive layer MTL1 may be disposed between the first sensing insulation layer 71 and the second sensing insulation layer 72, and the second sensing conductive layer MTL2 may be disposed between the second sensing insulation layer 72 and the third sensing insulation layer 73. A portion of the second sensing conductive layer MTL2 may be connected with the first sensing conductive layer MTL1 through a contact hole CNT formed in the second sensing insulation layer 72. Each of the first sensing conductive layer MTL1 and the second sensing conductive layer MTL2 may have a single-layer structure or may have a multi-layer structure stacked in the third direction DR3.

A sensing conductive layer having a single-layer structure may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), or the like. Alternatively, the transparent conductive layer may include a conductive polymer such as PEDOT, a metal nano-wire, or graphene.

A sensing conductive layer having a multi-layer structure may include metal layers. The metal layers may have, for example, a three-layer structure of titanium (Ti)/aluminum (Al)/titanium (Ti). Alternatively, the multi-layered sensing conductive layer may include at least one metal layer and at least one transparent conductive layer.

In the sensing layer ISL, the first sensing conductive layer MTL1 and the second sensing conductive layer MTL2 may together form a sensor configured to detect an external input. The sensor may operate based on a capacitive sensing method or be a sensor of a capacitive type. The sensor may be driven in either a mutual capacitive mode or a self-capacitive mode. However, the embodiments are not limited thereto. For example, the sensor may be driven in a resistive, an ultrasonic, or an infrared type, in addition to the capacitance type but is not limited to any one embodiment.

Each of the first sensing conductive layer MTL1 and the second sensing conductive layer MTL2 may include a transparent conductive oxide and may have a metal mesh shape formed of an opaque conductive material. As long as the visibility of an image displayed by the display panel DP does not deteriorate, the first sensing conductive layer MTL1 and the second sensing conductive layer MTL2 may have various materials and shapes and are not limited to any one embodiment.

FIG. 16 is a sectional view of a display panel according to an embodiment of the present disclosure. In describing FIG. 16, components identical or similar to the components described with reference to FIGS. 14 to 15 will be assigned with identical or similar reference numerals, and repetitive descriptions will be omitted. The following description will be focused mainly on the difference.

Referring to FIG. 16, the display panel DP-1 may further include the connecting line CN-ad disposed between the sixth insulating layer 60 and the pixel defining layer PDL. The connecting line CN-ad may be connected to the intermediate connecting electrode CN through the through-hole OP-60 that exposes at least a portion of the intermediate connecting electrode CN.

In an embodiment of the present disclosure, the connecting line CN-ad may be disposed on the same layer as the first electrode EL1. For example, the connecting line CN-ad may have the same material and the same layer structure as the first electrode EL1. In addition, the connecting line CN-ad may be formed by the same process as that of the first electrode EL1. However, this is merely an example, and the present disclosure is not limited thereto. For example, the connecting line CN-ad may include a material different from that of the first electrode EL1 and may be formed by a process different from that of the first electrode EL1.

A through-hole OP-Pa may be defined in the pixel defining layer PDL. In an embodiment, the through-hole OP-Pa and the through-hole OP-60 do not overlap each other, but are not limited thereto. For example, in other embodiments, the through-hole OP-Pa and the through-hole OP-60 may overlap each other. The connecting electrode CNE may be disposed in the through-hole OP-Pa. The connecting electrode CNEa may be connected to a portion of the connecting line CN-ad exposed by the through-hole OP-Pa.

According to an embodiment of the present disclosure, the cathode of the light emitting element may be electrically connected with the drain of the drive transistor. The drive transistor in the pixel drive circuit may be an N-type transistor, and at least one of the switching transistors may be a P-type transistor. Accordingly, the maximum voltage value required to turn on and off the transistors in the pixel drive circuit may be lowered. Thus, the voltage difference between the maximum voltage value and the minimum voltage value may be reduced, and the pixel with reduced power consumption and the display device including the same may be provided.

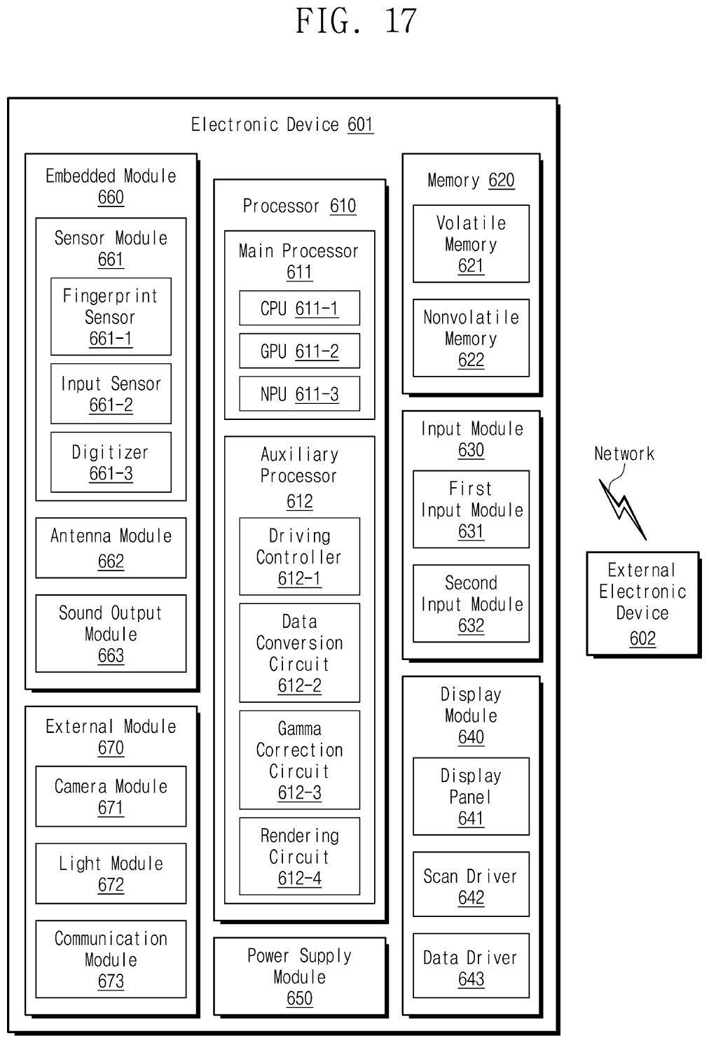

FIG. 17 is a block diagram of an electronic device, according to an embodiment of the present disclosure.

Referring to FIG. 17, an electronic device 601 outputs various pieces of information through a display module 640 within an operating system. When a processor 610 executes an application stored in a memory 620, a display module 640 provides application information to a user through a display panel 641.

The processor 610 obtains an external input through an input module 630 or a sensor module 661 and executes an application corresponding to the external input. For example, when the user selects a camera icon displayed on the display panel 641, the processor 610 obtains a user input through an input sensor 661-2 and activates a camera module 671. The processor 610 delivers image data corresponding to a captured image obtained through the camera module 671 to the display module 640. The display module 640 may display an image corresponding to the captured image through the display panel 641.

For another example, when personal information is authenticated on the display module 640, a fingerprint sensor 661-1 obtains entered fingerprint information as input data. The processor 610 compares input data obtained through the fingerprint sensor 661-1 with authentication data stored in the memory 620 and executes an application based on the comparison result. The display module 640 may display information, which is executed depending on the logic of the application, through the display panel 641.

For another example, when a music streaming icon displayed on the display module 640 is selected, the processor 610 obtains a user input through the input sensor 661-2 and activates the music streaming application stored in the memory 620. When a music play command is input by the music streaming application, the processor 610 provides sound information corresponding to the music play command to the user by activating a sound output module 663.

The operation of the electronic device 601 has been briefly described above. Hereinafter, a configuration of the electronic device 601 will be described in detail. Some of components of the electronic device 601, which will be described below, may be integrated and provided as one configuration, or the one configuration may be provided to be separated into two or more configurations.

Referring to FIG. 17, the electronic device 601 may communicate with an external electronic device 602 through a network (e.g., a short-range wireless communication network or a long-range wireless communication network). According to an embodiment, the electronic device 601 may include the processor 610, the memory 620, the input module 630, the display module 640, a power supply module 650, an embedded module 660, and an external module 670. According to an embodiment, in the electronic device 601, at least one of the above-described components may be omitted, or one or more other components may be added. According to an embodiment, some (e.g., the sensor module 661, an antenna module 662, or the sound output module 663) of the components described above may be integrated into another component (e.g., the display module 640).

The processor 610 may execute software to control at least another component (e.g., hardware or software component) of the electronic device 601 connected to the processor 610, and may process and calculate various types of data. According to an embodiment, as at least part of data processing or calculation, the processor 610 may store instructions or data received from other components (e.g., the input module 630, the sensor module 661 or a communication module 673) into a volatile memory 621, may process instructions or data stored in the volatile memory 621. The result data may be stored in a nonvolatile memory 622.

The processor 610 may include a main processor 611 and an auxiliary processor 612. The main processor 611 may include one or more of a central processing unit (CPU) 611-1 or an application processor (AP). The main processor 611 may further include one or more of a graphic processing unit (GPU) 611-2, a communication processor (CP), and an image signal processor (ISP). The main processor 611 may further include a neural processing unit (NPU) 611-3. The NPU 611-3 may be a processor that is specialized in processing an artificial intelligence model. The artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but may not be limited to the above-described example. In addition to a hardware structure, additionally or alternatively, the artificial intelligence model may include a software structure. At least two of the processing units and the processors that are described above may be implemented as one integrated component (e.g., a single chip) or may be implemented as independent components (e.g., a plurality of chips).

The auxiliary processor 612 may include a driving controller 612-1. The driving controller 612-1 may include an interface converting circuit and a timing control circuit. The driving controller 612-1 receives an image signal from the main processor 611, converts the data format of the image signal so as to be suitable for the interface specifications with the display module 640, and outputs image data. The driving controller 612-1 may output various control signals required to drive the display module 640. The configuration of the driving controller 612-1 is substantially similar to the drive controller 100 shown in FIG. 1, and thus detailed descriptions are omitted to avoid redundancy.

The auxiliary processor 612 may further include a data converting circuit 612-2, a gamma correcting circuit 612-3, and a rendering circuit 612-4. The data converting circuit 612-2 may receive the image data from the driving controller 612-1 and may compensates for the image data such that an image is displayed at a desired luminance according to characteristics of the electronic device 601 or setting of the user or may convert the image data to reduce power consumption or compensate for afterimages. The gamma correcting circuit 612-3 may convert the image data, a gamma reference voltage, or the like such that the image displayed on the electronic device 601 has desired gamma characteristics. The rendering circuit 612-4 may receive the image data from the driving controller 612-1 and may render the image data in consideration of a pixel arrangement of the display panel 641 applied to the electronic device 601. At least one of the data converting circuit 612-2, the gamma correcting circuit 612-3, and the rendering circuit 612-4 may be integrated into another component (e.g., the main processor 611 or the driving controller 612-1). At least one of the data converting circuit 612-2, the gamma correcting circuit 612-3, and the rendering circuit 612-4 may be integrated into a data driver 643.

The memory 620 may store various pieces of data, which are used by at least one component (e.g., the processor 610 or the sensor module 661) of the electronic device 601 and input data or output data for commands related thereto. The memory 620 may include at least one or more of the volatile memory 621 and the nonvolatile memory 622.

The input module 630 may receive, from the outside (e.g., the user or an external electronic device 602) of the electronic device 601, commands or data to be used in a components (e.g., the processor 610, the sensor module 661, or the sound output module 663) of the electronic device 601.

The input module 630 may include a first input module 631, through which the commands or data are input from the user, and a second input module 632 through which the commands or data are input from the external electronic device 602. The first input module 631 may include a microphone, a mouse, a keyboard, a key (e.g., a button), or a pen (e.g., a passive pen or an active pen). The second input module 632 may support a designated protocol capable of being connected to the external electronic device 602 by wire or wirelessly. According to an embodiment, the second input module 632 may include a high definition multimedia interface (HDMI), a universal serial bus (USB) interface, a secure digital (SD) card interface, or an audio interface. The second input module 632 may include a connector that may be physically connected to the external electronic device 602, for example, an HDMI connector, a USB connector, an SD card connector, or an audio connector (e.g., a headphone connector).

The display module 640 provides visual information to the user. The display module 640 may include the display panel 641, a scan driver 642, and the data driver 643. The display module 640 may further include a window, a chassis, a bracket, or the like for protecting the display panel 641. The display module 640 may further include a light emitting driver, a voltage generator, and the like. The voltage generator may output various voltages (e.g., the first and second driving voltages ELVDD and ELVSS (see FIG. 1)) required to drive the display panel 641. The configuration of the display panel 641, the scan driver 642, the data driver 643, and the voltage generator is substantially similar to the configuration of the display panel DP, scan drive circuit SD, light emission drive circuit EDC, the data drive circuit 200, and the voltage generator 300 shown in FIG. 1, and thus detailed descriptions are omitted to avoid redundancy.

The power supply module 650 supplies power to the components of the electronic device 601. The power supply module 650 may include a battery that charges a power voltage. The battery may include a non-rechargeable primary cell, a rechargeable secondary cell, a fuel cell, or the like. The power supply module 650 may include a power management integrated circuit (PMIC). The PMIC supplies optimized power to the above-described modules and modules which will be described below. The power supply module 650 may include a wireless power transmission/reception member electrically connected to the battery. The wireless power transmission/reception member may include a plurality of coil-shaped antenna radiators.

The electronic device 601 may further include the embedded module 660 and the external module 670. The embedded module 660 may include the sensor module 661, the antenna module 662, and the sound output module 663. The external module 670 may include the camera module 671, a light module 672, and the communication module 673.

The sensor module 661 may detect an input from the user's body or an input from a pen among the first input module 631, and may generate an electrical signal or data value corresponding to the input. The sensor module 661 may include at least one of the fingerprint sensor 661-1, the input sensor 661-2, and a digitizer 661-3.

The fingerprint sensor 661-1 may generate a data value corresponding to a fingerprint of the user. The fingerprint sensor 661-1 may include one of an optical-type fingerprint sensor, or a capacitance-type fingerprint sensor.

The input sensor 661-2 may generate a data value corresponding to coordinate information of an input by a body of the user or an input by a pen. The input sensor 661-2 generates the change in capacitance due to the input as the data value. The input sensor 661-2 may sense an input by a passive pen or may transmit or receive data to or from an active pen.

The input sensor 661-2 may also measure a biometric signal such as blood pressure, moisture, or body fat. For example, when the user touches a part of the body to a sensor layer or sensing panel and does not move during a specific period, the input sensor 661-2 may detect the biometric signal and may output information desired by the user to the display module 640 based on a changes in electric fields caused by the part of the body.

The digitizer 661-3 may generate the data value corresponding to coordinate information of an input by the pen. The digitizer 661-3 generates an electromagnetic change amount due to the input as the data value. The digitizer 661-3 may sense input by the passive pen or transmit or receive data to or from the active pen.

At least one of the fingerprint sensor 661-1, the input sensor 661-2, and the digitizer 661-3 may be implemented as a sensor layer formed on the display panel 641 through a subsequent process. The fingerprint sensor 661-1, the input sensor 661-2, and the digitizer 661-3 may be placed on the upper side of the display panel 641, and one (e.g., the digitizer 661-3) of the fingerprint sensor 661-1, the input sensor 661-2, and the digitizer 661-3 may be placed on the lower side of the display panel 641.

At least two or more of the fingerprint sensor 661-1, the input sensor 661-2, and the digitizer 661-3 may be formed to be integrated into one sensing panel through the same process. When being integrated into one sensing panel, the sensing panel may be placed between the display panel 641 and a window placed on the upper side of the display panel 641. According to an embodiment, the sensing panel may be placed on a window, and the location of the sensing panel is not particularly limited thereto.

At least one of the fingerprint sensor 661-1, the input sensor 661-2, and the digitizer 661-3 may be built into the display panel 641. That is, at least one of the fingerprint sensor 661-1, the input sensor 661-2, and the digitizer 661-3 may be simultaneously formed through a process of forming elements (e.g., a light emitting element, a transistor, or the like) included in the display panel 641.

Besides, the sensor module 661 may generate an electrical signal or a data value corresponding to the internal state or external state of the electronic device 601. For example, the sensor module 661 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 662 may include one or more antennas to transmit or receive the signal or power to or from an external source. According to an embodiment, the communication module 673 may transmit or receive the signal to or from the external electronic device through the antenna suitable for a communication method. An antenna pattern of the antenna module 662 may be integrated into the input sensor 661-2 or one component (e.g., the display panel 641) of the display module 640.

The sound output module 663 may be a device for outputting an audio signal to the outside of the electronic device 601 and, for example, may include a speaker used for general purposes, such as multimedia playback or recording playback, and a receiver used only for receiving a call. According to an embodiment, the receiver may be implemented separately from the speaker or may be integrated with the speaker. A sound output pattern of the sound output module 663 may be integrated into the display module 640.

The camera module 671 may shoot a still image or a video image. According to an embodiment, the camera module 671 may include one or more lenses, an image sensor, or an image signal processor. The camera module 671 may further include an infrared camera capable of measuring the presence or absence of the user, a position of the user, a gaze of the user, or the like.

The light module 672 may provide light. The light module 672 may include a light emitting diode or a xenon lamp. The light module 672 may operate in conjunction with the camera module 671 or may operate independently from the camera module 1710.

The communication module 673 may support establishing a wired or wireless communication channel between the electronic device 601 and the external electronic device 602 and performing communication through the established communication channel. The communication module 673 may include one or all of wireless communication modules such as a cellular communication module, a short-range wireless communication module, or a global navigation satellite system (GNSS) communication module, or wired communication modules such as a local area network (LAN) communication module or a power line communication module. The communication module 673 may communicate with the external electronic device 602 through a short-range communication network such as Bluetooth, WiFi direct, or infrared data association (IrDA) or a long-range communication network such as a cellular network, Internet, or a computer network (e.g., the LAN or a wide area network (WAN)). The above-mentioned various communication modules 673 may be implemented into one chip or may be respectively implemented into separate chips.

The input module 630, the sensor module 661, the camera module 671, and the like may be utilized to control an operation of the display module 640 in conjunction with the processor 610.

The processor 610 outputs commands or data to the display module 640, the sound output module 663, the camera module 671, or the light module 672 based on input data received from the input module 630. For example, the processor 610 may generate image data in response to input data applied through a mouse, an active pen, or the like to output the generated image data to the display module 640 or may generate command data in response to the input data to output the generated command data to the camera module 671 or the light module 672. When no input data is received from the input module 630 during a specific period, the processor 610 may switch an operation mode of the electronic device 601 to a low-power mode or a sleep mode to reduce power consumed in the electronic device 601.

The processor 610 outputs commands or data to the display module 640, the sound output module 663, the camera module 671, or the light module 672 based on sensing data received from the sensor module 661. For example, the processor 610 may compare authentication data authorized by the fingerprint sensor 661-1 with the authentication data stored in the memory 620, and then may execute an application depending on the comparison result. The processor 610 may execute commands or may output corresponding image data to the display module 640 based on sensing data sensed by the input sensor 661-2 or the digitizer 661-3. When the sensor module 661 includes a temperature sensor, the processor 610 receives temperature data regarding the measured temperature from the sensor module 661 and may further perform luminance correction on image data based on the temperature data.

The processor 610 may receive measurement data regarding the presence or absence of the user, the user's location, and the user's gaze from the camera module 671. The processor 610 may further perform luminance correction on the image data based on the measurement data. For example, the processor 610 that determines the presence or absence of the user through an input from the camera module 671 may output image data, of which the luminance is corrected, to the display module 640 through the data converting circuit 612-2 or the gamma correcting circuit 612-3.

Some of the components may be connected to each other through communication methods between peripheral devices, for example, a bus, a general purpose input/output (GPIO), a serial peripheral interface (SPI), a mobile industry processor interface (MIPI), or an ultra-path interconnect (UPI) link and may exchange a signal (e.g., commands or data) between each other. The processor 610 may communicate with the display module 640 through a mutually promised interface, and for example, may use any one of the above-described communication methods, and the present disclosure is not limited to the above-described communication methods.

The electronic device 601 according to various embodiments disclosed in the specification may be implemented with various types of devices. The electronic device 601 may include, for example, at least one of a portable communication device (e.g., a smart phone), a computer device, a portable multimedia device, a portable medical device, a camera, a wearable device, or a home appliance. The electronic device 601 according to an embodiment of this specification may not be limited to the above-described devices.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a pixel including a light emitting element and a pixel drive circuit connected to the light emitting element, the light emitting element being connected between a first power line configured to receive a first power voltage and a first node,
wherein the pixel drive circuit includes:
a first transistor including a first electrode electrically connected to the first node, a second electrode electrically connected to a second node, and a gate electrode electrically connected to a third node;
a second transistor including a first electrode electrically connected to a data line configured to receive a data signal, a second electrode electrically connected to the third node, and a gate electrode configured to receive a scan signal; and
a third transistor including a first electrode electrically connected to a first initialization voltage line configured to receive a first initialization voltage, a second electrode electrically connected to the first node, and a gate electrode configured to receive a compensation scan signal,
wherein the first transistor is an N-type transistor,
wherein the second transistor is an N-type transistor or a P-type transistor, and
wherein the third transistor is a P-type transistor.

2. The display device of claim 1, wherein the pixel drive circuit further includes a fourth transistor including a first electrode electrically connected to a reference voltage line configured to receive a reference voltage, a second electrode electrically connected to the third node, and a gate electrode configured to receive an initialization scan signal,
wherein the fourth transistor is an N-type transistor or a P-type transistor.

3. The display device of claim 2, wherein during an initialization period, the initialization scan signal has an active level, and the compensation scan signal and the scan signal have an inactive level, and
wherein during a compensation period, the compensation scan signal and the initialization scan signal have an active level, and the scan signal has an inactive level.

4. The display device of claim 1, wherein the pixel drive circuit further includes:
a first capacitor connected between the second node and the third node; and
a second capacitor connected between the second node and a second power line configured to receive a second power voltage having a lower voltage level than the first power voltage.

5. The display device of claim 1, wherein the pixel drive circuit further includes a fifth transistor including a first electrode electrically connected to the first node, a second electrode electrically connected to the first electrode of the first transistor, and a gate electrode configured to receive a first light emission signal,
wherein the fifth transistor is a P-type transistor.

6. The display device of claim 5, wherein the pixel drive circuit further includes a sixth transistor including a first electrode electrically connected to the second node, a second electrode electrically connected to a second power line configured to receive a second power voltage having a lower voltage level than the first power voltage, and a gate electrode configured to receive a second light emission signal,
wherein the sixth transistor is an N-type transistor or a P-type transistor.

7. The display device of claim 6, wherein a high level of the compensation scan signal and a high level of the first light emission signal is less than or equal to 10V.

8. The display device of claim 6, wherein during an initialization period, the second light emission signal has an active level, and the first light emission signal has an inactive level, and
wherein during a compensation period, the first light emission signal has an active level, and the second light emission signal has an inactive level.

9. The display device of claim 6, wherein a voltage value of the first power voltage is less than or equal to 8.4V.

10. The display device of claim 9, wherein a voltage value of each of the first power voltage and the first initialization voltage is about 8.4V, a voltage value of the second power voltage is about 0V, and a high level of each of the compensation scan signal and the first light emission signal is about 8.4V.

11. The display device of claim 9, wherein a voltage value of each of the first power voltage and the first initialization voltage is about 7V, and a voltage value of the second power voltage is about 0V, and
wherein a high level of each of the compensation scan signal and the first light emission signal is about 7V.

12. The display device of claim 1, wherein the pixel drive circuit further includes:
a fifth transistor including a first electrode electrically connected to the first node, a second electrode electrically connected to the first electrode of the first transistor, and a gate electrode configured to receive a light emission signal; and
a sixth transistor including a first electrode electrically connected to the second node, a second electrode electrically connected to a second power line configured to receive a second power voltage having a lower voltage level than the first power voltage, and a gate electrode configured to receive the light emission signal, and
wherein each of the fifth transistor and the sixth transistor is a P-type transistor.

13. The display device of claim 12, wherein the pixel drive circuit further includes a seventh transistor including a first electrode electrically connected with the second node, a second electrode electrically connected with a second initialization voltage line configured to receive a second initialization voltage having a lower voltage level than the first initialization voltage, and a gate electrode configured to receive an input scan signal, and
wherein the seventh transistor is an N-type transistor.

14. The display device of claim 13, wherein during an initialization period, the input scan signal has an active level, and
wherein during a compensation period, the input scan signal has an inactive level.

15. The display device of claim 13, wherein the pixel drive circuit further includes an eighth transistor including a first electrode electrically connected to the first initialization voltage line, a second electrode electrically connected to the first electrode of the first transistor, and a gate electrode configured to receive the compensation scan signal, and
wherein the eighth transistor is a P-type transistor.

16. The display device of claim 12, wherein a voltage value of the first power voltage is about 8.4V, a voltage value of the second power voltage is about 0V, and a high level of the light emission signal is less than or equal to 10V, and
wherein a voltage value of the first initialization voltage is about 8.4V, and a high level of the compensation scan signal is less than or equal to 10V.

17. The display device of claim 1, wherein the light emitting element includes an anode, a cathode disposed over the anode, and at least an emissive layer and includes an intermediate layer disposed between the anode and the cathode, and
wherein the anode is electrically connected to the first power line, and the cathode is electrically connected to the first node.

18. The display device of claim 17, further comprising:
a pixel defining layer including an opening configured to expose at least a portion of the anode;
a connecting electrode disposed on the pixel defining layer and electrically connected to the first node and the cathode; and
a separator disposed on the pixel defining layer,
wherein, in a contact area adjacent to the separator, a lower surface of the cathode is in contact with an upper surface of the connecting electrode.

19. A display device comprising:
a light emitting element connected between a first power line configured to receive a first power voltage and a first node, the light emitting element including a first electrode, an intermediate layer disposed on the first electrode and an emissive layer, and a second electrode disposed on the intermediate layer;
a pixel drive circuit connected to the light emitting element, the pixel drive circuit including a drive transistor and a plurality of switching transistors;
a pixel defining layer including an opening configured to expose at least a portion of the first electrode;
a connecting electrode disposed on the pixel defining layer and electrically connected to the pixel drive circuit and the second electrode; and
a separator disposed on the pixel defining layer,
wherein in a contact area adjacent to the separator, a lower surface of the second electrode is in contact with an upper surface of the connecting electrode,
wherein the drive transistor is an N-type transistor, and
wherein at least one of the plurality of switching transistors is a P-type transistor.

20. An electronic device comprising:
a display device configured to provide an image; and
a processor to control an operation of the display device,
the display device comprising:
a pixel including a light emitting element and a pixel drive circuit connected to the light emitting element, the light emitting element being connected between a first power line configured to receive a first power voltage and a first node,
wherein the pixel drive circuit includes:
a first transistor including a first electrode electrically connected to the first node, a second electrode electrically connected to a second node, and a gate electrode electrically connected to a third node;
a second transistor including a first electrode electrically connected to a data line configured to receive a data signal, a second electrode electrically connected to the third node, and a gate electrode configured to receive a scan signal; and
a third transistor including a first electrode electrically connected to a first initialization voltage line configured to receive a first initialization voltage, a second electrode electrically connected to the first node, and a gate electrode configured to receive a compensation scan signal,
wherein the first transistor is an N-type transistor,
wherein the second transistor is an N-type transistor or a P-type transistor,
wherein the third transistor is a P-type transistor.
